(19) United States
(12) Patent Application Publication
(10) Pub. No.: US 2025/0126956 A1
(43) Pub. Date: Apr. 17, 2025

(54) Driving Backplane, Light-Emitting Substrate and Display Device

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Hai Tang, Beijing (CN); Xinxin Zhao, Beijing (CN)

(21) Appl. No.: 18/688,021

(22) PCT Filed: Sep. 26, 2022
(86) PCT No.: PCT/CN2022/121421

§ 371 Date: Feb. 29, 2024

(51) Int. Cl. H10H 29/85; G02F 1/13357; H01L 25/075; H10H 29/80; H10H 29/852; H10H 29/856

(52) U.S. Cl. CPC H10H 29/857; G02F 1/133603; H01L 25/0753; H10H 29/852; H10H 29/856; H10H 29/942

(57) ABSTRACT

A driving backplane includes a substrate, a plurality of pad groups, and a plurality of marks. The plurality of pad groups and the plurality of marks are located on a same side of the substrate, a pad group includes at least one pad, and orthogonal projections of the plurality of marks on the substrate and orthogonal projections of the plurality of pad groups on the substrate have no overlap. The pad group corresponds to at least one mark. An orthogonal projection of the at least one mark on the substrate is located on a circumference of an orthogonal projection of a corresponding area of the pad group on the substrate, is adjacent to an orthogonal projection of the pad group on the substrate, and has a first gap from the orthogonal projection of the pad group on the substrate.

### CROSS-REFERENCE TO RELATED APPLICATION

This application is the United States national phase of International Patent Application No. PCT/CN2022/121421, filed Sep. 26, 2022, the disclosure of which is hereby incorporated by reference in its entirety.

### BACKGROUND OF THE INVENTION

### Field of the Invention

The present disclosure relates to the field of display technologies, and in particular, to a driving backplane, a light-emitting substrate and a display device.

### Description of Related Art

Micro light-emitting diodes (LED) or submillimeter light-emitting diodes (mini LED) have attracted more and more attention due to their small size, low power consumption, long product life and other advantages. The micro LED refers to a LED with a chip size less than 100 μm, and the mini LED refers to a LED with a chip size of 100 μm to 300 μm. The manufacturing process of a micro light-emitting diode light panel or a submillimeter light-emitting diode light panel includes a lot of processes such as a die bonding process, an automated optical inspection (AOI) process, a reworking process and a bonding process, where the die bonding process refers to a process of transferring chips on a wafer to a driving backplane and bonding the chips to the driving backplane.

### SUMMARY OF THE INVENTION

In an aspect, a driving backplane is provided. The driving backplane includes a substrate, a plurality of pad groups and a plurality of marks. The plurality of pad groups are located on a side of the substrate, and a pad group includes one or more pads. The plurality of marks are located on a same side of the substrate as the plurality of pad groups, and orthogonal projections of the plurality of marks on the substrate and orthogonal projections of the plurality of pad groups on the substrate have no overlap. The pad group corresponds to one or more marks, and orthogonal projections of the one or more marks on the substrate are located on a circumference of an orthogonal projection of a corresponding area of the pad group on the substrate, are each adjacent to an orthogonal projection of the pad group on the substrate, and each have a gap from the orthogonal projection of the pad group on the substrate.

In some embodiments, the pad group corresponds to multiple marks. Orthogonal projections of the multiple marks on the substrate are arranged at intervals along the circumference of the orthogonal projection of the corresponding area of the pad group on the substrate.

In some embodiments, the pad group corresponds to multiple marks. An orthogonal projection of a geometric center of each mark on the substrate has an approximately equal distance from an orthogonal projection of a geometric center of the corresponding area of the pad group on the substrate, and an orthogonal projection of a geometric center of the multiple marks on the substrate substantially coincides with the orthogonal projection of the geometric center of the corresponding area of the pad group on the substrate.

In some embodiments, at least one mark is located between two adjacent pad groups, and the two adjacent pad groups share the at least one mark located between the two adjacent pad groups.

In some embodiments, the driving backplane further includes at least one conductive layer and one or more insulating layers. The at least one conductive layer is located on a side of the substrate, and each conductive layer includes a plurality of connection lines. An insulating layer is included on a side of the at least one conductive layer away from the substrate. In a case where the driving backplane includes a plurality of conductive layers, at least one insulating layer is included between two adjacent conductive layers. The plurality of marks are disposed in the at least one conductive layer.

In some embodiments, the plurality of marks include at least one first mark, and a conductive layer where the first mark is located is a first target conductive layer. An orthogonal projection of the first mark on the substrate is not overlapped with orthogonal projections of a plurality of connection lines in the first target conductive layer on the substrate.

In some embodiments, the plurality of marks include at least one second mark, and a conductive layer where the second mark is located is a second target conductive layer. The second mark is connected to an edge of a connection line in the second target conductive layer, and an outer contour of the second mark protrudes from an outer contour of the connection line.

In some embodiments, the plurality of marks include at least one third mark, and a conductive layer where the third mark is located is a third target conductive layer. The one or more insulating layers include an upper insulating layer, and the upper insulating layer is located on a side of the third target conductive layer away from the substrate. The upper insulating layer includes a plurality of first openings, an orthogonal projection of a first opening on the substrate is located within an orthogonal projection of a connection line in the third target conductive layer on the substrate, and a portion of the connection line located in the first opening serves as a third mark.

In some embodiments, the connection line where the third mark is located is a target connection line, and the target connection line includes a first extension section and a second extension section. The orthogonal projection of the first opening on the substrate is located within an orthogonal projection of the first extension section on the substrate, a line width of the first extension section is greater than a line width of the second extension section, and a shape of at least one side edge of the first extension section is substantially same as a shape of at least part of a border of the first opening.

In some embodiments, the at least one conductive layer includes a first conductive layer, the first conductive layer is located on the side of the substrate, and the first conductive layer includes a plurality of first connection lines. The one or more insulating layers include a first insulating layer, and the first insulating layer is located on a side of the first conductive layer away from the substrate. The plurality of marks are disposed in the first conductive layer.

In some embodiments, the at least one conductive layer includes a first conductive layer and a second conductive layer, and the first conductive layer is further away from the substrate than the second conductive layer. The first conductive layer includes a plurality of first connection lines, and the second conductive layer includes a plurality of second connection lines. The one or more insulating layers include a first insulating layer and a second insulating layer, the first insulating layer is located on a side of the first conductive layer away from the substrate, and the second insulating layer is located between the first conductive layer and the second conductive layer. The plurality of marks are disposed in the first conductive layer and/or the second conductive layer, and the plurality of marks include at least one of a first mark, a second mark and a third mark.

In some embodiments, the plurality of marks are disposed in the first conductive layer, and the plurality of marks include at least one of a first mark and a second mark. A material of the first insulating layer includes a transparent material; and/or the first insulating layer is provided with a plurality of second openings therein, and an orthogonal projection of a mark on the substrate is at least partially located within an orthogonal projection of a second opening on the substrate.

In some embodiments, the plurality of marks are disposed in the first conductive layer, and the plurality of marks include a plurality of third marks. A material of the first insulating layer includes a photoresist material.

In some embodiments, the plurality of marks are disposed in the second conductive layer, and orthogonal projections of the plurality of marks on the substrate and orthogonal projections of the plurality of first connection lines on the substrate have no overlap.

In some embodiments, the plurality of marks include at least one of the first mark and the second mark. A material of the first insulating layer includes a transparent material; and/or the first insulating layer is provided with a plurality of third openings therein, and an orthogonal projection of a mark on the substrate is at least partially located within an orthogonal projection of a third opening on the substrate. A material of the second insulating layer includes a transparent material; and/or the second insulating layer is provided with a plurality of fourth openings therein, and an orthogonal projection of the mark on the substrate is at least partially located within an orthogonal projection of a fourth opening on the substrate.

In some embodiments, the plurality of marks include the third mark. A material of the first insulating layer includes a photoresist material, and a material of the second insulating layer includes a transparent material. The first insulating layer is provided with a plurality of first openings therein, and an orthogonal projection of a first opening on the substrate is located within an orthogonal projection of a second connection line on the substrate. The second insulating layer is provided with a plurality of fifth openings therein, and a boundary of each fifth opening substantially coincides with a boundary of a first opening; or an orthogonal projection of the second insulating layer on the substrate covers orthogonal projections of the plurality of first openings on the substrate. Alternatively, the material of the second insulating layer includes a photoresist material, and the material of the first insulating layer includes a transparent material. The second insulating layer is provided with a plurality of first openings therein, and an orthogonal projection of a first opening on the substrate is located within the orthogonal projection of the second connection line on the substrate. The first insulating layer is provided with a plurality of sixth openings therein, and a boundary of each sixth opening substantially coincides with a boundary of a first opening; or an orthogonal projection of the first insulating layer on the substrate covers the orthogonal projections of the plurality of first openings on the substrate.

In some embodiments, the pad group corresponds to multiple marks. Orthogonal projections of the multiple marks corresponding to the pad group on the substrate are centrally symmetrical, and an orthogonal projection of a symmetry center of the multiple marks on the substrate substantially coincides with an orthogonal projection of a geometric center of the pad group on the substrate. The geometric center of the pad group refers to a geometric center of the corresponding area of the pad group.

In some embodiments, the pad group corresponds to two marks, and orthogonal projections of the two marks on the substrate are centrally symmetrical about the geometric center of the pad group.

In some embodiments, the pad group includes a plurality of pads, and the plurality of pads are configured to be bonded to a same chip. The pad group corresponds to multiple marks. An orthogonal projection of a geometric center of the pad group on the substrate substantially coincides with an orthogonal projection of a symmetry center of the multiple marks corresponding to the pad group on the substrate.

In some embodiments, the pad group includes a plurality of pads, and the plurality of pads are configured to be bonded to a plurality of chips. The pad group corresponds to multiple marks. An orthogonal projection of a geometric center of a corresponding area of multiple pads bonded to at least one chip on the substrate substantially coincides with an orthogonal projection of a symmetry center of at least part of the multiple marks on the substrate.

In some embodiments, the pad group includes two first pads, two second pads, two third pads and a plurality of fourth pads. The two first pads are configured to be bonded to a first light-emitting chip for emitting light of a first color, the two second pads are configured to be bonded to a second light-emitting chip for emitting light of a second color, the two third pads are configured to be bonded to a third light-emitting chip for emitting light of a third color, and the plurality of fourth pads are configured to be bonded to a driver chip. The orthogonal projection of the symmetry center of the at least part of the multiple marks on the substrate substantially coincides with an orthogonal projection of a geometric center of a whole of the two first pads, the two second pads and the two third pads on the substrate, or substantially coincides with an orthogonal projection of a geometric center of the plurality of four pads on the substrate, or substantially coincides with an orthogonal projection of a geometric center of the pad group on the substrate.

In some embodiments, the two first pads, the two second pads and the two third pads are each arranged side by side in a first direction, and the two first pads, the two second pads and the two third pads are arranged in a second direction. The first direction intersects the second direction. In the first direction, the plurality of fourth pads are located on a side of the whole of the two first pads, the two second pads and the two third pads.

In some embodiments, shapes of orthogonal projections of the marks on the substrate are one or more of a circle, a rectangle, a regular polygon, or a cross.

In another aspect, a light-emitting substrate is provided. The light-emitting substrate includes the driving backplane as described in any of the above embodiments, a plurality of chips and an encapsulation layer. A chip is bonded to at least one pad of the one or more pads in the pad group. The encapsulation layer is located on a side of the plurality of marks and the plurality of pad groups away from the substrate, and provided with a plurality of seventh openings therein. An orthogonal projection of the at least one pad bonded to the chip on the substrate is located within an orthogonal projection of a seventh opening on the substrate.

In some embodiments, an orthogonal projection of at least one mark, in the one or more marks, corresponding to the at least one pad on the substrate is located within the orthogonal projection of the seventh opening on the substrate.

In some embodiments, the encapsulation layer includes a reflective layer. The reflective layer is provided with a plurality of eighth openings therein, and an orthogonal projection of a mark on the substrate is located within an orthogonal projection of an eighth opening on the substrate.

In some embodiments, the encapsulation layer includes a reflective layer. Orthogonal projections of the plurality of marks on the substrate are located within an orthogonal projection of the reflective layer on the substrate.

In yet another aspect, a backlight module is provided. The backlight module includes the light-emitting substrate as described in any of the above embodiments and an optical film disposed on a light-exiting side of the light-emitting substrate. The encapsulation layer of the light-emitting substrate includes a reflective layer.

In yet another aspect, a display device is provided. The display device includes the backlight module as described in any of the above embodiments and a display panel disposed on a light-exiting side of the backlight module.

In yet another aspect, a display device is provided. The display device includes the light-emitting substrate as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a sectional view taken along a section line A-A in FIG. 1;

FIG. 3 is a structural diagram of a backlight module, in accordance with some embodiments;

FIG. 4 is a structural diagram of a light-emitting substrate, in accordance with some embodiments;

FIG. 5A is a partial enlarged view of a region B in FIG. 4;

FIG. 5B is a partial enlarged view of a region C in FIG. 4;

FIG. 6A is a sectional view taken along a section line D-D in FIG. 5A;

FIG. 6B is another sectional view taken along a section line D-D in FIG. 5A;

FIG. 7 is yet another sectional view taken along a section line D-D in FIG. 5A;

FIGS. 8A to 8E are each a positional relationship diagram of a pad group and corresponding mark(s), in accordance with some embodiments;

FIG. 9 is a distance relationship diagram of a pad group and a corresponding mark, in accordance with some embodiments;

FIG. 10 is a structural diagram of two adjacent pad groups and corresponding marks, in accordance with some embodiments;

FIG. 11 is a structural diagram of a conductive layer, in accordance with some embodiments;

FIG. 12A is a partial enlarged view of a region E in FIG. 11;

FIG. 12B is another partial enlarged view of a region E in FIG. 11;

FIG. 12C is a structural diagram of a driving backplane, in accordance with some embodiments;

FIGS. 13A and 13B are each a structural diagram of another light-emitting substrate, in accordance with some embodiments;

FIGS. 14A to 14D are each a structural diagram of another light-emitting substrate, in accordance with some embodiments;

FIGS. 15A to 15E are each a structural diagram of another light-emitting substrate, in accordance with some embodiments;

FIGS. 16A to 16D are each a structural diagram of a pad group and corresponding marks, in accordance with some embodiments;

FIGS. 17A to 17D are structural diagrams of marks of different shapes, in accordance with some embodiments;

FIGS. 18A to 18C are each a structural diagram of a pad group bonded to a plurality of chips, in accordance with some embodiments;

FIG. 19 is a structural diagram of another pad group bonded to a plurality of chips, in accordance with some embodiments;

FIG. 20 is a structural diagram of yet another pad group bonded to a plurality of chips, in accordance with some embodiments;

FIG. 21 is yet another sectional view taken along a section line D-D in FIG. 5A;

FIG. 22 is a top view of FIG. 21;

FIG. 23 is yet another sectional view taken along a section line D-D in FIG. 5A;

FIG. 24 is a top view of FIG. 23;

FIG. 25 is yet another sectional view taken along a section line D-D in FIG. 5A;

FIG. 26 is a top view of FIG. 25;

FIG. 27 is yet another sectional view taken along a section line D-D in FIG. 5A; and

FIG. 28 is yet another sectional view taken along a section line D-D in FIG. 5A.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “connected” and derivatives thereof may be used. For example, the term “connected” may be used in the description of some embodiments to indicate that two or more components are in direct physical or electrical contact with each other.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context.

The phrase “applicable to” or “configured to” as used herein indicates an open and inclusive expression, which does not exclude devices that are applicable to or configured to perform additional tasks or steps.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

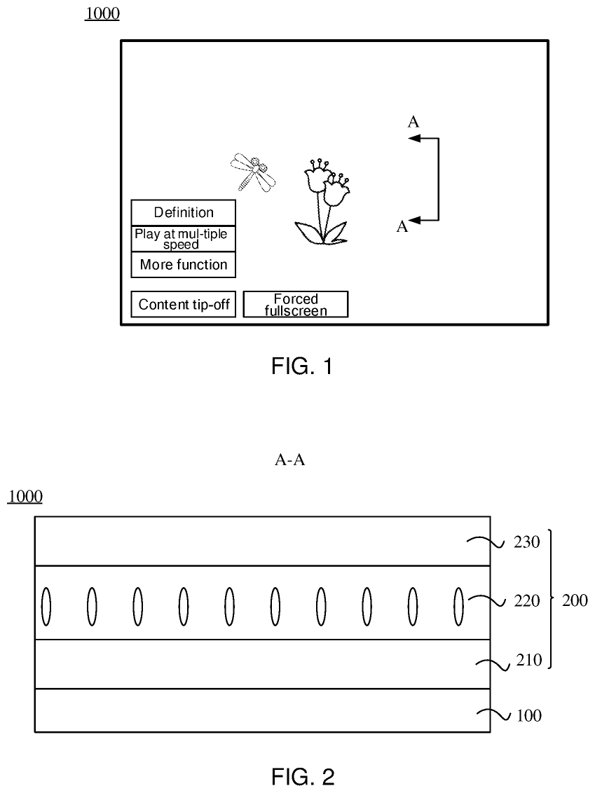

Embodiments of the present disclosure provide a display device 1000. As shown in FIG. 1, the display device 1000 is a device or apparatus for visually displaying electronic information. For example, the display device 1000 may be a smartphone, a tablet computer, a notebook computer, a display, or a television.

In some embodiments, as shown in FIG. 2, the display device 1000 includes a backlight module 100 and a display panel 200 disposed on a light-exiting side of the backlight module 100. The display panel 200 includes an array substrate 210, a liquid crystal layer 220 and a color film substrate 230 that are stacked. The array substrate 210 is closer to the backlight module 100 than the color film substrate 230. The light-exiting side of the backlight module 100 refers to a side from which the backlight module 100 emits light.

For example, the above backlight module 100 may be used as a light source to provide backlight. For example, the backlight provided by the backlight module 100 may be white light or blue light.

For example, the array substrate 210 may include a plurality of pixel driving circuits and a plurality of pixel electrodes. The plurality of pixel driving circuits are arranged in an array. The plurality of pixel driving circuits are electrically connected to the plurality of pixel electrodes in one-to-one correspondence, and the pixel driving circuit provides a pixel voltage for a corresponding pixel electrode.

For example, the liquid crystal layer 220 includes a plurality of liquid crystal molecules. For example, an electric field may be formed between the pixel electrode and a common electrode, and liquid crystal molecules located between the pixel electrode and the common electrode may be deflected due to action of the electric field.

For example, the color film substrate 230 may include color filters. For example, in a case where the backlight provided by the backlight module 100 is white light, the color filters may include red filter portions, green filter portions and blue filter portions. The red filter portion may only allow red light in the incident light to pass through, the green filter portion may only allow green light in the incident light to pass through, and the blue filter portion may only allow blue light in the incident light to pass through. For another example, in a case where the backlight provided by the backlight module 100 is blue light, the color filters may include red filter portions and green filter portions.

It can be understood that the backlight module 100 provides backlight, and the light may pass through the array substrate 210 to be incident onto the liquid crystal molecules in the liquid crystal layer 220. The liquid crystal molecules are deflected due to action of the electric field generated between the pixel electrode and the common electrode, so as to change the amount of light passing through the liquid crystal molecules, so that the light exiting through the liquid crystal molecules reaches a preset brightness. The light passes through filter portions of different colors in the color film substrate 230 and then exits. The above exiting light has a variety of colors, such as red, green and blue. The light of various colors cooperate with each other, so that the display device 1000 displays an image.

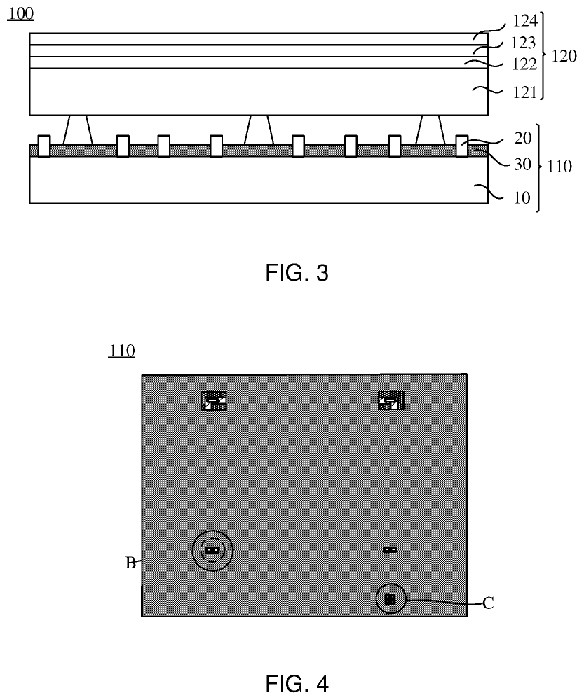

In some embodiments, as shown in FIG. 3, the backlight module 100 includes a light-emitting substrate 110 and an optical film 120 located on a light-exiting side of the light-emitting substrate 110. The light-exiting side of the light-emitting substrate 110 refers to a side from which the light-emitting substrate 110 emits light.

For example, the optical film 120 includes a diffusion plate 121, a quantum dot film 122, a diffusion sheet 123 and a composite film 124 that are stacked on the light-exiting side of the light-emitting substrate 110. The diffusion plate 121 is closer to the light-emitting substrate 110 than the composite film 124.

For example, the diffusion plate 121 and the diffusion sheet 123 are used to reduce risk of light shadows, and to uniformize the light emitted by the light-emitting substrate 110, so as to improve the uniformity of the emitted light.

The quantum dot film 122 is used to convert the light emitted by the light-emitting substrate 110. For example, in a case where the light emitted by the light-emitting substrate 110 is blue light, the quantum dot film 122 may convert the blue light into white light, which may improve purity of the white light. For another example, the quantum dot film 122 may convert the blue light into red light and green light, and thus the color filters in the color film substrate 230 may be omitted, and further the thickness of the display device 1000 may be reduced.

The composite film 124 is used to increase brightness of light emitted by the light-emitting substrate 110.

The light emitted by the light-emitting substrate 110 is incident on the optical film 120 and then exits from the optical film 120. As a result, the exiting light has an enhanced brightness, a rather high purity and a rather good uniformity.

In some other embodiments, the display device 1000 includes a light-emitting substrate 110, that is, the light-emitting substrate 110 is directly used for display instead of serving as a backlight source. The light-emitting substrate 110 may emit light of various colors, such as red light, green light and blue light. The red light, the green light and the blue light cooperate with each other, so that the display device 1000 displays an image.

In some embodiments, as shown in FIG. 3, the light-emitting substrate 110 includes a driving backplane 10, a plurality of chips 20 and an encapsulation layer 30.

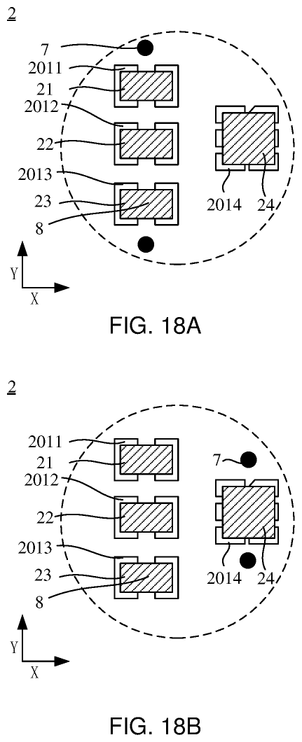

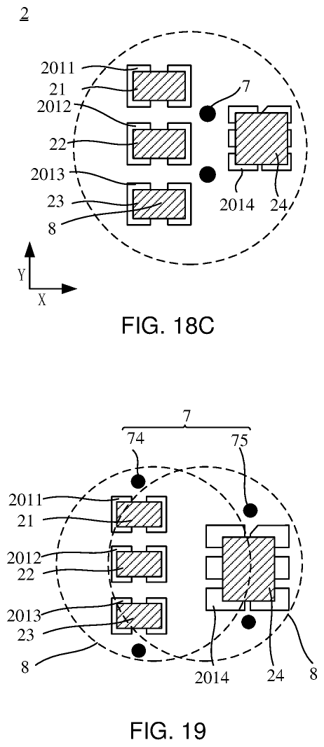

In some embodiments, as shown in FIGS. 18A to 20, the plurality of chips 20 may include at least one of first light-emitting chips 21 for emitting light of a first color, second light-emitting chips 22 for emitting light of a second color, third light-emitting chips 23 for emitting light of a third color, and a driver chip 24. The first color, the second color and the third color are not limited in the embodiments of the present disclosure, and may be three primary colors or other colors. For example, the first color, the second color and the third color are red, green and blue, respectively.

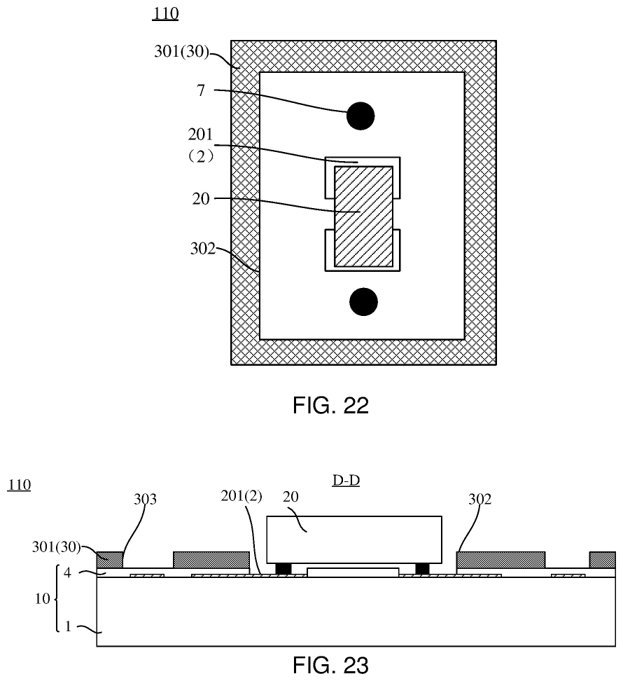

In a case where the light-emitting substrate 110 is used as a backlight source, the plurality of chips 20 may include first light-emitting chips 21 for emitting light of the first color. The first color may be blue or white, and the first color is not limited in the embodiments of the present disclosure. As shown in FIGS. 22 to 28, the encapsulation layer 30 includes a reflective layer 301.

The light-emitting substrate 110 may be formed by a reflective pre-process or a reflective post-process. The reflective pre-process refers to that a step of forming the reflective layer 301 is performed before a step of fixing the chips 20 (die bonding). The reflective post-processing process refers to that the step of forming the reflective layer 301 is performed after the step of fixing the chips 20.

The material of the reflective layer 301 includes white ink. The material of the white ink may include one or more of epoxy resin, polytetrafluoroethylene resin, titanium dioxide, and dipropylene glycol methyl ether, and are not listed one by one in the embodiments of the present disclosure.

For example, in a case where the display panel 200 includes a color film substrate 230 (the color film substrate 230 including color filters), the first color may include white.

For example, in a case where the backlight module 100 includes a quantum dot film 122, the first color may include blue.

In a case where the light-emitting substrate 110 is directly used for display, the plurality of chips may include first light-emitting chips 21 for emitting light of the first color, second light-emitting chips 22 for emitting light of the second color, third light-emitting chips 23 for emitting light of the third color, and the driver chip 24. For example, the first color, the second color and the third color are red, green and blue, respectively.

In some embodiments, as shown in FIGS. 4, 5A, 5B, 6A and 6B (the chip 20 is not shown in the figures), the driving backplane 10 includes a substrate 1 and a plurality of pad groups 2.

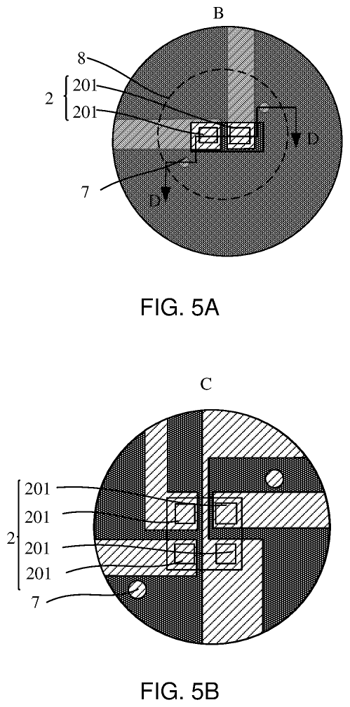

The plurality of pad groups 2 are located on a side of the substrate 1, and a pad group 2 includes at least one pad 201. For example, a pad group 2 may include one pad 201, two pads 201, or four pads 201, and the embodiments of the present disclosure do not list one by one. For example, as shown in FIG. 5A, a pad group 2 includes two pads 201. For another example, as shown in FIG. 5B, a pad group includes four pads 201.

In some embodiments, the driving backplane 10 further includes at least one conductive layer 3 and at least one insulating layer 4. For example, the driving backplane 10 further includes one conductive layer 3, two conductive layers 3 or three conductive layers 3, and the embodiments of the present disclosure do not list one by one. The driving backplane 10 further includes one insulating layer 4, two insulating layers 4 or three insulating layers 4, and the embodiments of the present disclosure do not list one by one. The at least one conductive layer 3 is located on a side of the substrate 1, and each conductive layer 3 includes a plurality of connection lines. An insulating layer 4 is provided on a side of each of the at least one conductive layer 3 away from the substrate 1. In a case where the driving backplane 10 includes a plurality of conductive layers 3, at least one insulating layer 4 is provided between two adjacent conductive layers 3.

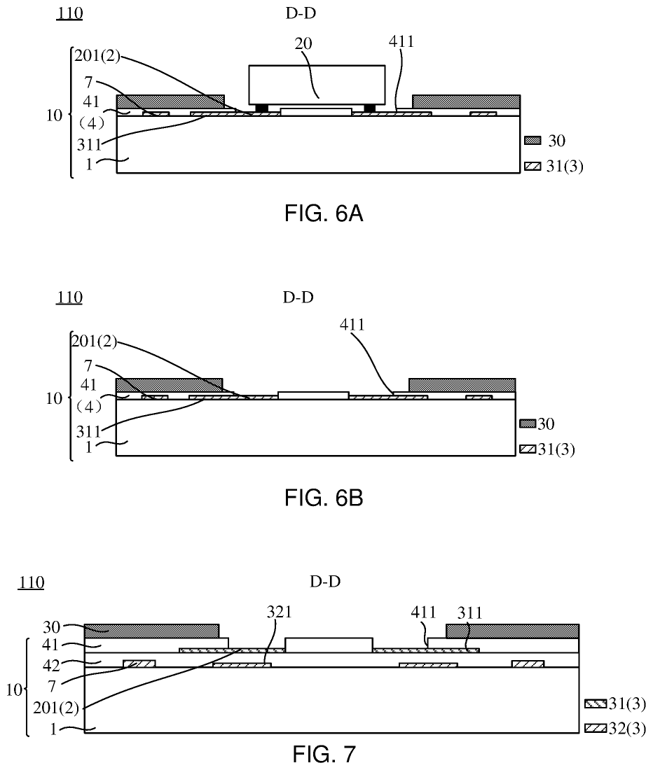

For example, as shown in FIGS. 6A and 6B, the at least one conductive layer 3 includes a first conductive layer 31, and the at least one insulating layer 4 includes a first insulating layer 41. That is, the driving backplane 10 further includes one conductive layer 3 and one insulating layer 4. The driving backplane 10 further includes the first conductive layer 31 and the first insulating layer 41.

The first conductive layer 31 is located on a side of the substrate 1, and the first conductive layer 31 includes a plurality of first connection lines 311. The material of the first conductive layer 31 may include metal, and the material of the metal may be silver (also referred to as Argentum, Ag), aluminum (Al) or copper (also referred to as Cuprum, Cu). The embodiments of the present disclosure do not list one by one. For example, the material of the first conductive layer 31 may include copper.

The first conductive layer 31 may be formed as a laminated structure by magnetron sputtering. For example, the first conductive layer 31 includes a first base layer, a first transmission signal layer and a first protective layer that are staked in a direction perpendicular to the substrate 1 and away from the substrate 1. The first base layer is provided on the substrate 1, and the first base layer is used to bond the substrate 1 to the first transmission signal layer. For example, the material of the first base layer includes MoNb (300 Å). The first transmission signal layer is provided on a side of the first base layer away from the substrate 1, and the first transmission signal layer is used to transmit electrical signals between the plurality of chips 20. For example, the first transmission signal layer includes copper. The first protective layer is provided on a side of the first transmission signal layer away from the first base layer, and the first protective layer is used to reduce risk of oxidation of the material of the first transmission signal layer. For example, the material of the first protective layer includes MoNb (200 Å). For example, the structure of the first conductive layer 31 is a laminated structure of MoNb/Cu/MoNb. In a case where a thickness of the first conductive layer 31 is relatively large, since a thickness of a film layer formed by a single magnetron sputtering is restricted, multiple sputtering is required to form the first conductive layer 31.

The first conductive layer 31 may also be formed by electroplating, a seed layer MoNiTi is formed first to increase nucleation density of crystal grains, and then an anti-oxidation layer MoNiTi is formed after the electroplating.

The first insulating layer 41 is located on a side of the first conductive layer 31 away from the substrate 1. The material of the first insulating layer 41 may include silicon oxide, silicon nitride or silicon oxynitride, and the embodiments of the present disclosure do not list one by one.

In a case where the driving backplane 10 includes the first conductive layer 31 and the first insulating layer 41, the first conductive layer 31 includes first connection lines 311, and the first insulating layer 41 is further provided with a plurality of ninth openings 411 therein. A ninth opening 411 exposes a portion of a first connection line 311, and the portion of the first connection line 311 exposed by the ninth opening 411 forms a pad 201.

In some embodiments, as shown in FIG. 7, the at least one conductive layer 3 includes a first conductive layer 31 and a second conductive layer 32, and the at least one insulating layer 4 includes a first insulating layer 41 and a second insulating layer 42. That is, the driving backplane 10 includes two conductive layers 3 and two insulating layers 4. The driving backplane 10 further includes the first conductive layer 31, the second conductive layer 32, the first insulating layer 41 and the second insulating layer 42.

The first conductive layer 31 is further away from the substrate 1 than the second conductive layer 32. The first insulating layer 41 is located on a side of the first conductive layer 31 away from the substrate, and the second insulating layer 42 is located between the first conductive layer 31 and the second conductive layer 32. The second conductive layer 32 includes a plurality of second connection lines 321. The material of the second conductive layer 32 may be the same as the material of the first conductive layer 31. The material of the second insulating layer 42 may be the same as the material of the first insulating layer 41.

The second conductive layer 32 may also be formed as a laminated structure by magnetron sputtering. For example, the second conductive layer 32 includes a second base layer, a second transmission signal layer and a second protective layer that are staked in the direction perpendicular to the substrate 1 and away from the substrate 1. The second base layer is provided on the substrate 1, and the second base layer is used to bond the substrate 1 to the second transmission signal layer. For example, the material of the second base layer includes MoNb. The second transmission signal layer is provided on a side of the second base layer away from the substrate 1, and the second transmission signal layer is used to transmit electrical signals between the plurality of chips 20. For example, the second transmission signal layer includes copper. The second protective layer is provided on a side of the second transmission signal layer away from the second base layer, and the second protective layer is used to reduce risk of oxidation of the material of the second transmission signal layer and improve firmness of the chips 20. For example, the material of the second protective layer includes CuNi. The structure of the second conductive layer is a laminated structure of MoNb/Cu/CuNi.

The first base layer is disposed on the second insulating layer 42, and the first base layer is used to bond the second insulating layer 42 to the first transmission signal layer. The first transmission signal layer is provided on a side of the first base layer away from the substrate 1, and the first transmission signal layer includes copper. The first protective layer is provided on a side of the first transmission signal layer away from the first base layer.

In a case where the driving backplane 10 further includes a second conductive layer 32 and a second insulating layer 42, the first insulating layer 41 is further provided with a plurality of ninth openings 411 therein. A ninth opening 411 exposes a portion of a first connection line 311, and the portion of the first connection line 311 exposed by the ninth opening 411 forms a pad 201.

In the related art, in a case where the driving backplane needs to bond a large number of chips (e.g., the number of the chips is in the millions), it takes a relatively long time for die bonding. During the whole die bonding, in order to monitor quality of chip bonding, it is necessary to move the driving backplane and the bonded chips multiple times on a die bonder and an automated optical inspection instrument, that is, it is necessary to load and unload multiple times on the die bonder and the automated optical inspection instrument. In this way, it takes a relatively long time to detect the position accuracy of the chips.

In order to solve the above problem, as shown in FIGS. 6A, 6B and 7, the driving backplane 10 further includes a plurality of marks 7. The plurality of marks 7 and the plurality of pad groups 2 are located on the same side of the substrate 1. There is no overlap between orthogonal projections of the plurality of marks 7 on the substrate 1 and orthogonal projections of the plurality of pad groups 2 on the substrate 1. After the chip 20 is fixed on the pad group 2, the chip 20 will not block the mark 7. In this way, the risk of the optical inspection system failing to identify the mark 7 may be reduced.

As shown in FIG. 5A, a pad group 2 corresponds to at least one mark 7. An orthogonal projection of the at least one mark 7 on the substrate 1 is located on a circumference of an orthogonal projection of a corresponding area of the pad group 2 on the substrate 1 and is adjacent to an orthogonal projection of the pad group 2 on the substrate 1, and has a first gap from an orthogonal projection of the pad group 2 on the substrate 1. Being adjacent to the pad group 2 refers to that the pad group 2 and all the mark(s) 7 on the circumference of the corresponding area of the pad group 2 are located in the same reference area 8, that is, located within a lighting area generated by a same optical inspection system (an area enclosed by the dotted line in FIG. 5A).

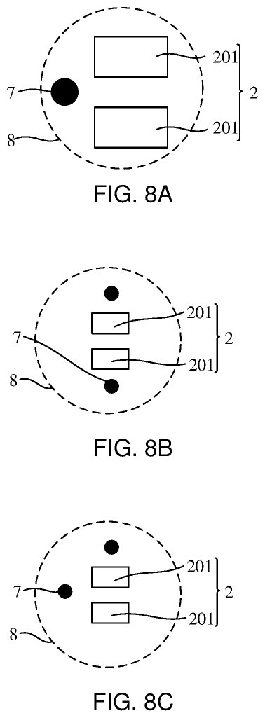

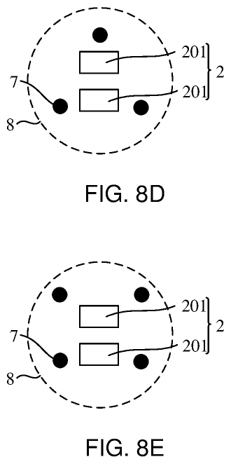

For example, as shown in FIG. 8A, a pad group 2 corresponds to a mark 7, and the pad group 2 and the corresponding mark 7 are located in the same reference area. As shown in FIGS. 8B and 8C, a pad group 2 corresponds to two marks 7, and the pad group 2 and the corresponding two marks 7 are located in the same reference area. As shown in FIG. 8D, a pad group 2 corresponds to three marks 7, and the pad group 2 and the corresponding three marks 7 are located in the same reference area. As shown in FIG. 8E, a pad group 2 corresponds to four marks 7, and the pad group 2 and the corresponding four marks 7 are located in the same reference area. The embodiments of the present disclosure do not list one by one.

The at least one mark 7 and the pad group having the first gap therebetween means that all the mark(s) 7 located on the circumference of the corresponding area of the pad group 2 each have a first gap from the pad group. A dimension of the first gap is greater than a dimension of bonding error of the chip 20 and a dimension of a safety electrical distance. For example, the dimension of the safety electrical distance is 30 μm.

The dimension of bonding error of the chip 20 refers to a distance between an orthogonal projection of a geometric center of the chip 20 on the substrate 1 and an orthogonal projection of a geometric center of the pad group 2 on the substrate 1 in a case where the chip 20 is bonded to the driving backplane 10 and the position accuracy of the chip 20 is qualified (that is, the chip 20 will not block the mark 7).

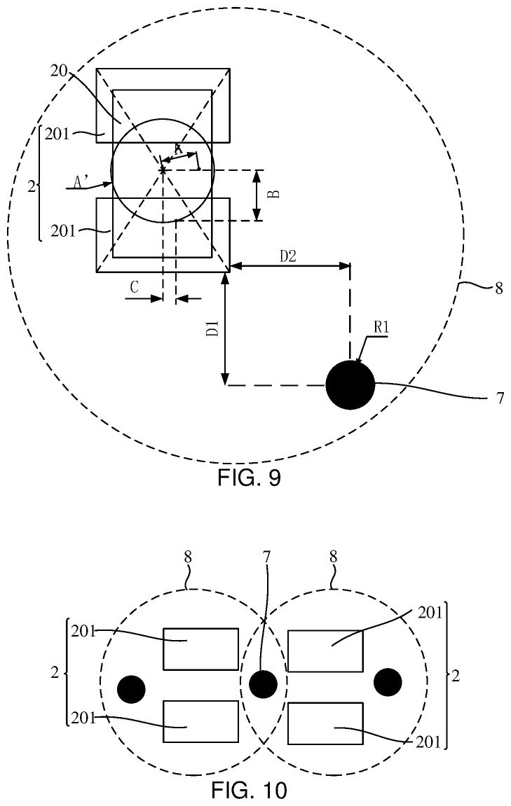

For example, as shown in FIG. 9, in a case where an orthogonal projection of the chip 20 on the substrate 1 is in a shape of a rectangle and an orthogonal projection of the mark 7 on the substrate is in a shape of a circle, as shown in FIG. 9, a distance between a center of the orthogonal projection of the chip 20 on the substrate 1 and a center of the orthogonal projection of the pad group 2 bonded to the chip 20 on the substrate 1 is A. A value A′ is preset, and a circle is drawn with the geometric center of the pad group 2 as a center of the circle and A′ as a radius. In a case where A is greater than A′ (i.e., the geometric center of the chip 20 falls outside the circle), the position accuracy of the chip 20 is unqualified. In a case where A is less than or equal to A′ (i.e., the geometric center of the chip 20 falls within the circle), the position accuracy of the chip 20 is qualified.

In a length direction of the chip 20, a distance between the center of the orthogonal projection of the mark 7 on the substrate 1 and an edge of the orthogonal projection of the pad group on the substrate 1 is D1, and a distance between an actual geometric center of the chip 20 and the geometric center of the pad group 2 is B. In a width direction of the chip 20, a distance between the center of the orthogonal projection of the mark 7 on the substrate 1 and the edge of the orthogonal projection of the pad group on the substrate 1 is D2, and a distance between the actual geometric center of the chip 20 and the geometric center of the pad group 2 is C.

The relationship of B, C, D1, D2 and a radius of the mark R1 is that D1 is greater than or equal to a sum of R1 and B (i.e., D1≥R1+B), and D2 is greater than or equal to a sum of R1+C (i.e., D2≥R1+C). In this way, after the chip 20 is fixed on the pad group 2, the chip 20 will not block the mark 7, so that the risk of the optical inspection system failing to identify the mark 7 caused by the mark 7 being blocked by the chip 20 may be reduced.

The reference area 8 is an overlapped area between the lighting area generated by the optical inspection system and a reference surface. The reference surface is approximately parallel to the substrate 1, and the plurality of marks 7 are located in the reference surface. In this way, the optical inspection system may calculate the geometric center of the pad group 2 (i.e., a theoretical geometric center of the chip 20) through at least one mark 7 corresponding to the pad group 2. Then, the optical inspection system compares the theoretical geometric center of the chip 20 with the actual geometric center of the chip 20 to determine the position accuracy of the chip 20. In this way, the optical inspection system on the die bonder may detect the positional accuracy of the chip 20 without loading and unloading multiple times between the die bonder and the automated optical inspection instrument, thereby reducing the time of the process of detecting the position accuracy of the chips 20.

The geometric center of the pad group 2 refers to the geometric center of the corresponding area of the pad group 2. In a case where the pad group 2 includes one pad 201, the geometric center of the corresponding area of the pad group 2 refers to a geometric center of an orthogonal projection of the pad 201 on the substrate 1. In a case where the pad group 2 includes a plurality of pads 201, the geometric center of the corresponding area of the pad group 2 refers to a geometric center of an orthogonal projection of an area composed of the plurality of pads 201 as a whole on the substrate 1 instead of a geometric center of an orthogonal projection of each pad 201 included in the pad group 2 on the substrate 1.

A pad group 2 refers to a plurality of pads that share the same at least one mark 7 (all marks 7 used for an optical inspection). For example, in a case where a pad group 2 corresponds to a mark 7, all of the plurality of pads 201 for detecting the position accuracy of the chip 20 through the same mark 7 are a pad group 2. Alternatively, in a case where a pad group 2 corresponds to multiple marks 7, all of the plurality of pads 201 for detecting the position accuracy of the chip 20 through the same multiple marks 7 are a pad group 2.

In some embodiments, during detecting the position accuracy of the chips 20, the optical inspection system may extract several chips 20 bonded to the driving backplane 10 for detection. If the position accuracy of the extracted chips 20 is all qualified, it can be inferred that the position accuracy of chips 20 bonded in the same batch as these chips 20 is qualified. In this way, the time of the process of detecting the position accuracy of the chips 20 may further be reduced.

In some other embodiments, during detecting the position accuracy of the chips 20, the optical inspection system may detect each chip 20 bonded to the driving backplane 10. In this way, the detection is rather comprehensive and the detection results are rather accurate, and the risk of damage to the light-emitting substrate 110 caused by poor position accuracy of the chips 20 may be reduced.

In some embodiments, a pad group 2 corresponds to multiple marks 7, and the multiple marks 7 are arranged at intervals along the circumference of the corresponding area of the pad group 2. That is, the multiple marks 7 are not located on a same side of the corresponding area of the pad group 2. For example, the multiple marks 7 are arranged at equal intervals along the circumference of the corresponding area of the pad group 2. For example, as shown in FIGS. 8B and 8C, a pad group 2 corresponds to two marks 7, and the two marks 7 are arranged at intervals along the circumference of the corresponding area of the pad group 2. As shown in FIG. 8B, a mark 7 is located on an upper side of the corresponding area of the pad group 2, and another mark 7 is located on a lower side of the corresponding area of the pad group 2. As shown in FIG. 8C, a mark is located on an upper side of the corresponding area of the pad group 2, and another mark 7 is located on a left side of the corresponding area of the pad group 2. As shown in FIG. 8D, three marks 7 are arranged at intervals along the circumference of the corresponding area of the pad group 2, a mark 7 is located on a left side of the corresponding area of the pad group 2, another mark 7 is located on an upper side of the corresponding area of the pad group 2, and the other mark 7 is located on a right side of the corresponding area of the pad group 2. The embodiments of the present disclosure do not list one by one.

In some embodiments, a pad group 2 corresponds to multiple marks 7. An orthogonal projection of a geometric center of each mark 7 on the substrate has an approximately equal distance from an orthogonal projection of a geometric center of the corresponding area of the pad group 2 on the substrate, and an orthogonal projection of a geometric center of the multiple marks 7 on the substrate substantially coincides with the orthogonal projection of the geometric center of the corresponding area of the pad group 2 on the substrate. During identifying a theoretical geometric center of the chip 20, the optical inspection system only needs to find a geometric center of the multiple marks 7, and does not need to offset according to symmetry center of the multiple marks 7. In this way, difficulty of an algorithm in the optical inspection system may be reduced, and the time of the process of detecting the position accuracy of the chips 20 may be reduced. The geometric center of the multiple marks 7 refers to, in orthogonal projections onto the substrate 1, a geometric center of an orthogonal projection of an area composed of the multiple marks 7 as a whole on the substrate 1 instead of a geometric center of an orthogonal projection of each mark 7 on the substrate 1.

For example, as shown in FIG. 8B, a pad group 2 corresponds to two marks 7, and the geometric center of each mark 7 has an approximately equal distance from the geometric center of the corresponding area of the pad group 2, and a geometric center of the two marks 7 and the geometric center of the corresponding area of the pad group 2 are substantially coincided. As shown in FIG. 8D, a pad group 2 corresponds to three marks 7, and a geometric center of each of the three marks 7 has an approximately equal distance from the geometric center of the corresponding area of the pad group 2, and a geometric center of the three marks 7 and the geometric center of the corresponding area of the pad group 2 are substantially coincided. The embodiments of the present disclosure do not list one by one.

In some embodiments, as shown in FIG. 10, at least one mark 7 is located between two adjacent pad groups 2, and the two adjacent pad groups 2 share the at least one mark 7 located between the two adjacent pad groups 2. The at least one mark 7 is located between the two adjacent pad groups 2, which means that at least one mark 7 in all the marks 7 located along the circumference of the corresponding area of the pad group 2 is located between the two adjacent pad groups 2. The two adjacent pad groups 2 share the at least one mark 7 located between the two adjacent pad groups 2, which means that the two adjacent pad groups 2 share the at least one mark 7 in all the marks 7 located between the two adjacent pad groups 2. In this way, the number of the marks 7 may be reduced, and the manufacturing cost of the driving backplane 10 may be reduced.

For example, as shown in FIG. 10, a pad group 2 corresponds to two marks 7. Orthogonal projections of the two marks 7 on the substrate 1 are located on a circumference of an orthogonal projection of the corresponding area of the pad group 2 on the substrate 1. There is a gap between each of the two marks 7 and the pad group 2, and a mark 7 is located between two adjacent pad groups 2. The mark 7 corresponds to the two adjacent pad groups 2, that is, the mark 7 and each of the two adjacent pad groups 2 are located in a respective same reference area 8. The two adjacent pad groups 2 share the above mark 7.

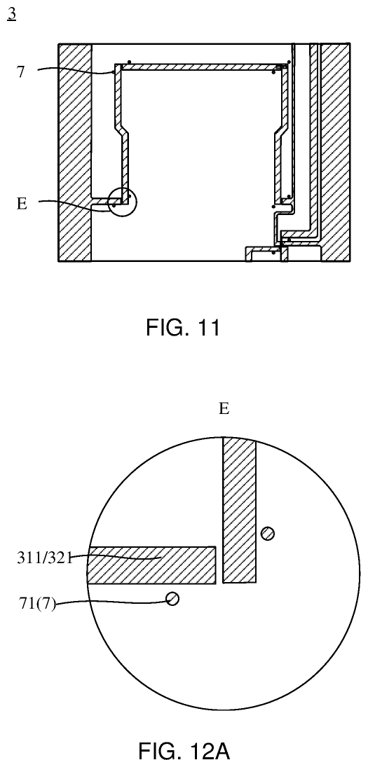

In some embodiments, as shown in FIG. 11, the plurality of marks 7 are provided in at least one conductive layer 3. In this way, the marks 7 and the conductive layer 3 may be formed through a patterning process, which may reduce the number of patterning. Therefore, the manufacturing cost may be reduced, and the production efficiency may be improved. The mark 7 may also be formed by laser etching, that is, the conductive layer 3 is first formed, and then the mark 7 is formed.

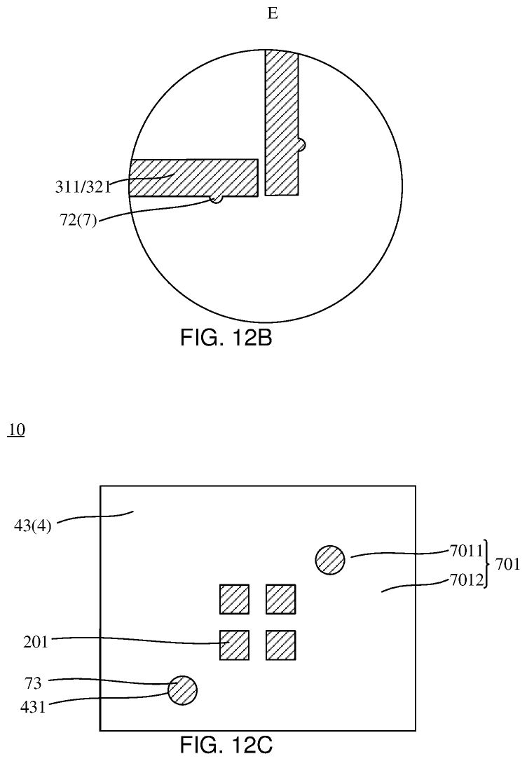

In some embodiments, as shown in FIG. 12A, the plurality of marks 7 include at least one first mark 71, and a conductive layer 3 where the first mark(s) 71 are located is a first target conductive layer 310. For example, in a case where the first mark(s) 71 are located in the first conductive layer 31, the first conductive layer 31 is the first target conductive layer. Alternatively, in a case where the first mark(s) 71 are located in the second conductive layer 32, the second conductive layer 32 is the first target conductive layer. Alternatively, in a case where the first marks 71 are respectively located in the first conductive layer 31 and the second conductive layer 32, the first conductive layer 31 and the second conductive layer 32 are both the first target conductive layers.

As shown in FIG. 12A, orthogonal projections of the first marks 71 on the substrate 1 do not overlap with orthogonal projections of a plurality of connection lines in the first target conductive layer on the substrate 1. In this way, the marks 7 and the plurality of connection lines do not affect each other, and the risk of the optical inspection system failing to identify the mark 7 may be reduced.

In some embodiments, as shown in FIG. 12B, the plurality of marks 7 further include at least one second mark 72, and a conductive layer where the second mark(s) 72 are located is a second target conductive layer 320. For example, in a case where the second mark(s) 72 are located in the first conductive layer 31, the first conductive layer 31 is the second target conductive layer. Alternatively, in a case where the second mark(s) 72 are located in the second conductive layer 32, the second conductive layer 32 is the second target conductive layer. Alternatively, in a case where the second marks 72 are respectively located in the first conductive layer 31 and the second conductive layer 32, the first conductive layer 31 and the second conductive layer 32 are both the second target conductive layers.

As shown in FIG. 12B, the second mark 72 is connected to an edge of a connection line in the second target conductive layer, and an outer contour of the second mark 72 protrudes from an outer contour of the connection line. Two ends of an oscilloscope or multimeter are respectively connected to second marks 72 at two ends of the connection line, and voltages are applied to the second marks 72 at the two ends of the connection line, so that it may be determined whether the connection line in the second target conductive layer is in a closed path or a break path by readings of the oscilloscope or multimeter.

In some embodiments, as shown in FIG. 12C, the plurality of marks 7 further include at least one third mark 73, and a conductive layer 3 where the third mark(s) 73 are located is a third target conductive layer 330. For example, in a case where the third mark(s) 73 are located in the first conductive layer 31, the first conductive layer 31 is the third target conductive layer. Alternatively, in a case where the third mark(s) 73 are located in the second conductive layer 32, the second conductive layer 32 is the third target conductive layer. Alternatively, in a case where the third marks 73 are located respectively in the first conductive layer 31 and the second conductive layer 32, the first conductive layer 31 and the second conductive layer 32 are both the third target conductive layers.

The at least one insulating layer 4 includes upper insulating layer(s) 43, and an upper insulating layer 43 is located on a side of a third target conductive layer away from the substrate 1. The upper insulating layer 43 is provided with a plurality of first openings 431 therein, and an orthogonal projection of a first opening 431 on the substrate 1 is located within an orthogonal projection of a connection line in the third target conductive layer on the substrate 1. A portion of the connection line located in the first opening 431 serves as a third mark.

For example, in a case where the first conductive layer 31 is the third target conductive layer, the first insulating layer 41 is the upper insulating layer 43, and the first insulating layer 41 is provided with a plurality of first openings 431 therein. An orthogonal projection of a first opening 431 on the substrate 1 is located within an orthogonal projection of a first connection line 311 in the first conductive layer 31 on the substrate 1. A portion of the first connection line 311 located in the first opening 431 serves as a third mark 73.

Alternatively, in a case where the second conductive layer 32 is the third target conductive layer, the second insulating layer 42 is the upper insulating layer 43, and the second insulating layer 42 is provided with a plurality of first openings 431 therein. An orthogonal projection of a first opening 431 on the substrate 1 is located within an orthogonal projection of a second connection line 321 in the second conductive layer 32 on the substrate 1. A portion of the second connection line 321 located in the first opening 431 serves as a third mark 73.

Alternatively, in a case where the first conductive layer 31 and the second conductive layer 32 are both the third target conductive layers, the first insulating layer and the second insulating layer 42 are both the upper insulating layers 43, and the first insulating layer 41 and the second insulating layer 43 are each provided with a plurality of first openings 431 therein. An orthogonal projection of a first opening 431 on the substrate 1 is located within an orthogonal projection of a first connection line 311 in the first conductive layer 31 on the substrate 1. An orthogonal projection of a first opening 431 on the substrate 1 is located within an orthogonal projection of a second connection line 321 in the second conductive layer 32 on the substrate 1, and a portion of the second connection line 321 located in the first opening 431 serves as a third mark 73.

For example, as shown in FIG. 12C, a connection line where the third mark 73 is located is a target connection line 701. The target connection line 701 may be a first connection line 311, a second connection line 321, or both the first connection line 311 and the second connection line 321. The target connection line 701 includes a first extension section 7011 and a second extension section 7012. An orthogonal projection of the first opening 431 on the substrate is located within an orthogonal projection of the first extension section 7011 on the substrate. A line width of the first extension section 7011 is greater than a line width of the second extension section 7012, and a shape of at least one side edge of the first extension section 7011 is substantially the same as a shape of at least part of a border of the first opening 431. For example, the border of the first opening 431 is in a shape of a circle, and the at least one side edge of the first extension section 7011 is in a shape of a semicircle.

In a case where the connection lines are formed not by exposure and development, that is, in a case where the manufacturing accuracy of the connection lines is low, there is no way to make small-sized marks 7 in the conductive layer 3. In this case, a plurality of first openings 431 may be provided in the upper insulation 43, and portions of connection lines exposed by first openings 431 serve as the third marks 73. For example, the material of the upper insulating layer 43 includes white ink, and the plurality of first openings 431 are formed by exposure and development.

In some embodiments, in a case where the at least one conductive layer 3 includes a first conductive layer 31, the plurality of marks 7 are provided in the first conductive layer 31. Alternatively, in a case where the at least one conductive layer 3 includes a first conductive layer 31 and a second conductive layer 32, the plurality of marks 7 are provided in the first conductive layer 31, or the plurality of marks 7 are provided in the second conductive layer 32, or some marks 7 in the plurality of marks 7 are provided in the first conductive layer 31 and some marks 7 in the plurality of marks 7 are provided in the second conductive layer 32. The embodiments of the present disclosure do not list one by one.

The plurality of marks 7 include at least one of first marks 71, second marks 72 and third marks 73. For example, the plurality of marks 7 include a first mark 71, a second mark 72, a third mark 73, the first mark 71 and the second mark 72, the second mark 72 and the third mark 73, the first mark 71 and the third mark 73, or the first mark 71, the second mark 72 and the third mark 73, which is not limited in the embodiments of the present disclosure.

In some embodiments, the plurality of marks 7 are provided in the first conductive layer 31, and the plurality of marks 7 include at least one of first marks 71 and second marks 72. For example, the plurality of marks 7 include the first marks 71, the second marks 72, or both the first mark 71 and the second mark 72, and the embodiments of the present disclosure do not list one by one.

The material of the first insulating layer 41 includes a transparent material; and/or the first insulating layer 41 is provided with a plurality of second openings 412 therein, and an orthogonal projection of a mark 7 on the substrate is at least partially located within an orthogonal projection of a second opening 412 on the substrate 1. In this way, the optical inspection system may identify the mark provided in the first conductive layer 31.

It can be understood that the transparent material includes a material with a light transmittance greater than or equal to 85%. For example, the light transmittance is 85%, 90% or 95%, and is not listed one by one in the embodiments of the present disclosure. For example, the transparent material may be polyethylene, polyvinyl chloride or transparent polytetrafluoroethylene, and is not listed one by one in the embodiments of the present disclosure.

The orthogonal projection of the mark 7 on the substrate 1 is at least partially located within the orthogonal projection of the second opening 412 on the substrate 1, which means that: a boundary of the orthogonal projection of the mark 7 on the substrate 1 is located within a boundary of the orthogonal projection of the second opening 412 on the substrate 1, and is spaced from the boundary of the orthogonal projection of the second opening 412 on the substrate 1; or the boundary of the orthogonal projection of the mark 7 on the substrate 1 and the boundary of the orthogonal projection of the second opening 412 on the substrate 1 substantially coincide with each other; or the boundary of the orthogonal projection of the mark 7 on the substrate 1 is located outside the boundary of the orthogonal projection of the second opening 412 on the substrate 1, and is spaced from the boundary of the orthogonal projection of the second opening 412 on the substrate 1.

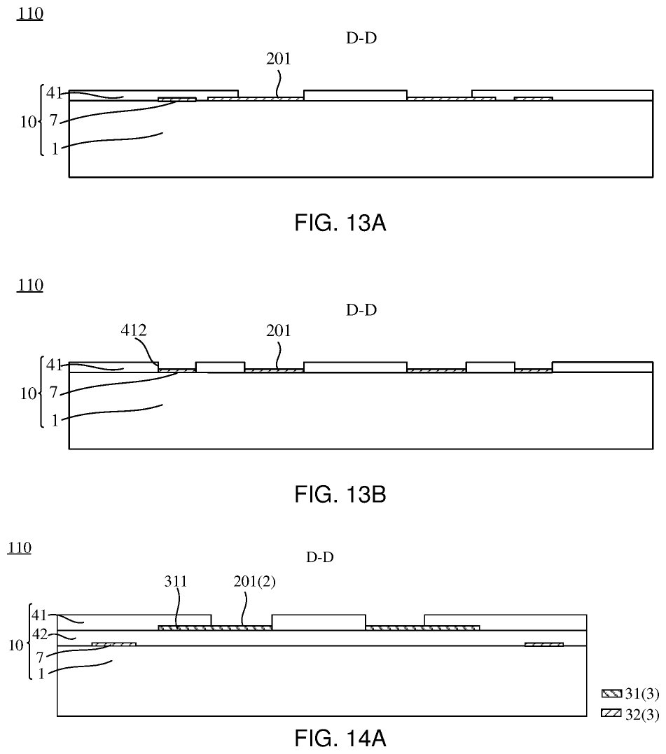

For example, as shown in FIG. 13A, the material of the first insulating layer 41 includes a transparent material, and the first insulating layer 41 is not provided with a second opening 412 therein. In this way, the optical inspection system may identify the mark 7 provided in the first conductive layer 31.

For example, as shown in FIG. 13B, the first insulating layer 41 is provided with a plurality of second openings 412 therein, and an orthogonal projection of a mark 7 on the substrate 1 is located within an orthogonal projection of a second opening 412 on the substrate 1. In this way, the optical inspection system may identify the mark 7 provided in the first conductive layer 31.

For example, as shown in FIG. 13B, the material of the first insulating layer 41 includes a transparent material. The first insulating layer 41 is provided with a plurality of second openings 412 therein, and an orthogonal projection of a mark 7 on the substrate 1 is located within an orthogonal projection of a second opening 412 on the substrate 1. In this way, it is possible to reduce the risk of the optical inspection system failing to identify the mark 7 further caused by inconsistent colors of multiple marks 7 identified by the optical inspection system due to the fluctuation of the thickness of the first insulating layer 41.

In some embodiments, the plurality of marks 7 are provided in the first conductive layer 31, and the plurality of marks 7 include a plurality of third marks 73. The material of the first insulating layer 41 includes a photoresist material, and the first insulating layer 41 is provided with a plurality of first openings 431 therein. An orthogonal projection of a first opening 431 on the substrate 1 is located within an orthogonal projection of a connection line in the first insulating layer 41 on the substrate 1. It can be understood that the photoresist material includes a material with a light transmittance less than or equal to 15%. For example, the light transmittance is 1%, 8% or 15%, and is not listed one by one in the embodiments of the present disclosure.

It can be understood that the plurality of marks 7 are provided in the first conductive layer 31, and the plurality of marks 7 may also include first marks 71 and the third marks 73, or second marks 72 and the third marks 73, or first marks 72, second marks 72 and the third marks 73.

In some embodiments, the plurality of marks 7 are provided in the second conductive layer 32. There is no overlap between orthogonal projections of the plurality of marks 7 on the substrate 1 and orthogonal projections of the plurality of first connection lines 311 on the substrate 1. In this way, it may reduce the risk of the optical inspection system failing to identify the marks 7 caused by the block of the marks 7 by the plurality of first connection lines 311.

The plurality of marks 7 include at least one of the first marks 71 and the second marks 72. For example, the plurality of marks 7 include the first marks 71, the second marks 72, or both the first marks 71 and the second marks 72, which is not limited in the embodiments of the present disclosure.

The material of the first insulating layer 41 includes a transparent material; and/or the first insulating layer 41 is provided with a plurality of third openings 413 therein, and an orthogonal projection of a mark 7 on the substrate 1 is at least partially located within an orthogonal projection of a third opening 413 on the substrate 1. Moreover, the material of the second insulating layer 42 includes a transparent material; and/or the second insulating layer 42 is provided with a plurality of fourth openings 422 therein, and an orthogonal projection of a mark 7 on the substrate 1 is at least partially located with an orthogonal projection of a fourth opening 422 on the substrate 1. In this way, the optical inspection system may identify the mark provided in the second conductive layer 32.

The orthogonal projection of the mark 7 on the substrate 1 is at least partially located within the orthogonal projection of the third opening 413 on the substrate 1, which means that a boundary of the orthogonal projection of the mark 7 on the substrate 1 is located within a boundary of the orthogonal projection of the third opening 413 on the substrate 1, and is spaced from the boundary of the orthogonal projection of the third opening 413 on the substrate 1; or the boundary of the orthogonal projection of the mark 7 on the substrate 1 and the boundary of the orthogonal projection of the third opening 413 on the substrate 1 substantially coincide with each other; or the boundary of the orthogonal projection of the mark 7 on the substrate 1 is located outside the boundary of the orthogonal projection of the third opening 413 on the substrate 1, and is spaced from the boundary of the orthogonal projection of the third opening 413 on the substrate 1.

The orthogonal projection of the mark 7 on the substrate 1 is at least partially located within the orthogonal projection of the fourth opening 422 on the substrate 1, which means that a boundary of the orthogonal projection of the mark 7 on the substrate 1 is located within a boundary of the orthogonal projection of the fourth opening 422 on the substrate 1, and is spaced from the boundary of the orthogonal projection of the fourth opening 422 on the substrate 1; or the boundary of the orthogonal projection of the mark 7 on the substrate 1 and the boundary of the orthogonal projection of the fourth opening 422 on the substrate 1 substantially coincide with each other; or the boundary of the orthogonal projection of the mark 7 on the substrate 1 is located outside the boundary of the orthogonal projection of the fourth opening 422 on the substrate 1, and is spaced from the boundary of the orthogonal projection of the fourth opening 422 on the substrate 1.

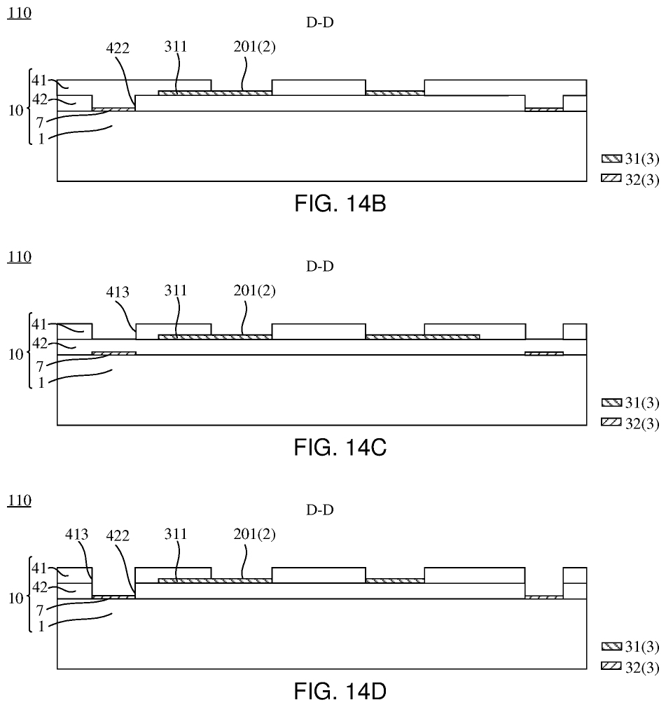

For example, as shown in FIG. 14A, the marks 7 are provided in the second conductive layer 32, and the materials of the first insulating layer 41 and the second insulating layer 42 both include transparent materials. In this way, the optical inspection system may identify the marks provided in the second conductive layer 32.

For example, as shown in FIG. 14B, the marks 7 are provided in the second conductive layer 32, the material of the first insulating layer 41 includes a transparent material, the second insulating layer 42 is provided with a plurality of fourth openings 422 therein, and an orthogonal projection of a mark 7 on the substrate 1 is at least partially located within an orthogonal projection of a fourth opening 422 on the substrate 1. In this way, the optical inspection system may identify the marks provided in the second conductive layer 32.

For example, as shown in FIG. 14B, the material of the first insulating layer 41 includes a transparent material, the material of the second insulating layer 42 includes a transparent material, the second insulating layer 42 is provided with a plurality of fourth openings 422 therein, and an orthogonal projection of a mark 7 on the substrate 1 is at least partially located within an orthogonal projection of a fourth opening 422 on the substrate 1. In this way, it is possible to reduce the risk of the optical inspection system failing to identify the mark 7 further caused by inconsistent colors of multiple marks 7 identified by the optical inspection system due to the fluctuation of the thickness of the second insulating layer 42.

For example, as shown in FIG. 14C, the first insulating layer 41 is provided with a plurality of third openings 413 therein. An orthogonal projection of a mark 7 on the substrate 1 is at least partially located within an orthogonal projection of a third opening 413 on the substrate 1. The material of the second insulating layer 42 includes a transparent material.

For example, as shown in FIG. 14D, the first insulating layer 41 is provided with a plurality of third openings 413 therein, and an orthogonal projection of a mark 7 on the substrate 1 is at least partially located within an orthogonal projection of a third opening 413 on the substrate 1. The second insulating layer 42 is provided with a plurality of fourth openings 422 therein, and an orthogonal projection of a mark 7 on the substrate 1 is at least partially located within an orthogonal projection of a fourth opening 422 on the substrate 1. A boundary of the third opening 413 and a boundary of the fourth opening 422 substantially coincide. In this way, the optical inspection system may identify the marks provided in the second conductive layer 32.

For example, as shown in FIG. 14D, the first insulating layer 41 is provided with a plurality of third openings 413 therein, and an orthogonal projection of a mark 7 on the substrate 1 is at least partially located within an orthogonal projection of a third opening 413 on the substrate 1. The material of the second insulating layer 42 includes a transparent material. The second insulating layer 42 is provided with a plurality of fourth openings 422 therein, and an orthogonal projection of a mark 7 on the substrate 1 is at least partially located within an orthogonal projection of a fourth opening 422 on the substrate 1. A boundary of the third opening 413 and a boundary of the fourth opening 422 substantially coincide. In this way, it is possible to reduce the risk of the optical inspection system failing to identify the mark 7 further caused by inconsistent colors of multiple marks 7 identified by the optical inspection system due to the fluctuation of the thickness of the second insulating layer 42.

For example, as shown in FIG. 14C, the material of the first insulating layer 41 includes a transparent material, the first insulating layer 41 is provided with a plurality of third openings 413 therein, and an orthogonal projection of a mark 7 on the substrate 1 is at least partially located within an orthogonal projection of a third opening 413 on the substrate 1. The material of the second insulating layer 42 includes a transparent material. In this way, it is possible to reduce the risk of the optical inspection system failing to identify the mark 7 further caused by inconsistent colors of multiple marks 7 identified by the optical inspection system due to the fluctuation of the thickness of the second insulating layer 42.

For example, as shown in FIG. 14D, the material of the first insulating layer 41 includes a transparent material, the first insulating layer 41 is provided with a plurality of third openings 413 therein, and an orthogonal projection of a mark 7 on the substrate 1 is at least partially located within an orthogonal projection of a third opening 413 on the substrate 1. The second insulating layer 42 is provided with a plurality of fourth openings 422 therein, and an orthogonal projection of a mark 7 on the substrate 1 is at least partially located within an orthogonal projection of a fourth opening 422 on the substrate 1. A boundary of the third opening 413 and a boundary of the fourth opening 422 substantially coincide. The optical inspection system may identify the marks provided in the second conductive layer 32.

For example, as shown in FIG. 14D, the materials of the first insulating layer 41 and the second insulating layer include transparent materials. The first insulating layer 41 is provided with a plurality of third openings 413 therein, and an orthogonal projection of a mark 7 on the substrate 1 is at least partially located within an orthogonal projection of a third opening 413 on the substrate 1. The second insulating layer 42 is provided with a plurality of fourth openings 422 therein, and an orthogonal projection of a mark 7 on the substrate 1 is at least partially located within an orthogonal projection of a fourth opening 422 on the substrate 1. A boundary of the third opening 413 and a boundary of the fourth opening 422 substantially coincide. In this way, it is possible to reduce the risk of the optical inspection system failing to identify the mark 7 further caused by inconsistent colors of multiple marks 7 identified by the optical inspection system due to the fluctuation of the thicknesses of the first insulating layer 41 and the second insulating layer 42.

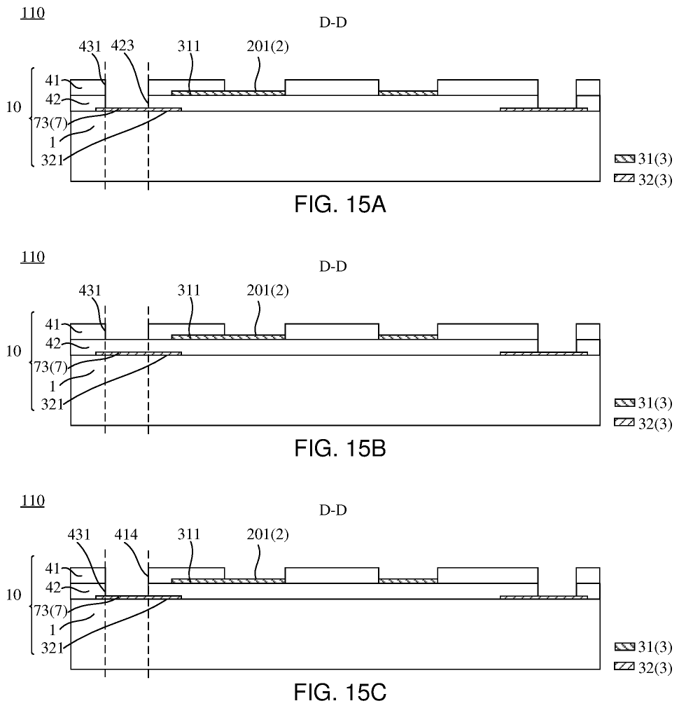

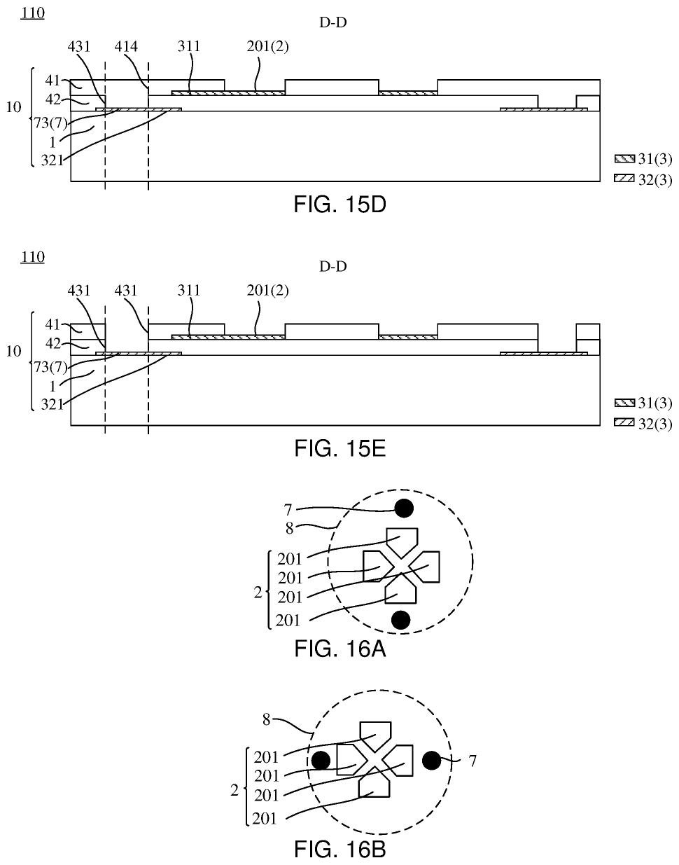

In some embodiments, as shown in FIGS. 15A to 15E, the plurality of marks are provided in the second conductive layer 32, and the plurality of marks 7 include third marks 73.

The material of the first insulating layer 41 includes a photoresist material, and the material of the second insulating layer 42 includes a transparent material. The first insulating layer 41 is provided with a plurality of first openings 431 therein, and an orthogonal projection of a first opening 431 on the substrate 1 is located within an orthogonal projection of a second connection line 321 on the substrate 1. As shown in FIG. 15A, the second insulating layer 42 includes a plurality of fifth openings 423, and a boundary of each fifth opening 423 and a boundary of a first opening 431 substantially coincide. Alternatively, as shown in FIG. 15B, an orthogonal projection of the second insulating layer 42 on the substrate 1 covers orthogonal projections of the plurality of first openings 431 on the substrate 1.

Alternatively, the material of the second insulating layer 42 includes a photoresist material, and the material of the first insulating layer 41 includes a transparent material. The second insulating layer 42 is provided with a plurality of first openings 431, and an orthogonal projection of a first opening 431 on the substrate 1 is located within an orthogonal projection of a second connection line 321 on the substrate 1. As shown in FIG. 15C, the first insulating layer 41 is provided with a plurality of sixth openings 414 therein, and a boundary of each sixth opening 414 and a boundary of a first opening 431 substantially coincide. Alternatively, as shown in FIG. 15D, an orthogonal projection of the first insulating layer 41 on the substrate 1 covers orthogonal projections of the plurality of first openings 431 on the substrate 1.

Alternatively, as shown in FIG. 15E, the materials of the first insulating layer 41 and the second insulating layer 42 both include photoresist materials. The first insulating layer 41 is provided with a plurality of first openings 431 therein, and an orthogonal projection of a first opening 431 on the substrate 1 is located within an orthogonal projection of a second connection line 321 on the substrate 1. The second insulating layer 42 is provided with a plurality of first openings 431 therein, and an orthogonal projection of a first opening 431 on the substrate 1 is located within an orthogonal projection of a second connection line 321 on the substrate 1. A boundary of each first opening 431 located in the first insulating layer 41 coincides with a boundary of a first opening 431 located in the second insulating layer 42.

In some embodiments, some marks 7 in the plurality of marks 7 are disposed in the first conductive layer 31, and some marks 7 in the plurality of marks are disposed in the second conductive layer 32. The some marks 7 provided in the first conductive layer 31 include at least one of a first mark 71, a second mark 72 and a third mark 73, and the some marks 7 provided in the second conductive layer 32 include at least one of a first mark 71, a second mark 72 and a third mark 73.

In some embodiments, as shown in FIG. 8A, a pad group 2 corresponds to a mark. During identifying a theoretical geometric center of the chip 20, the optical inspection system needs to find a geometric center of the mark 7 and shift according to the geometric center of the mark 7, and find a theoretical geometric center of the chip 20, and then compare the theoretical geometric center of the chip 20 with an actual center of the chip 20 to determine the position accuracy of the chip 20.

In some embodiments, as shown in FIG. 8B, a pad group 2 corresponds to multiple marks 7. Orthogonal projections of the multiple marks 7 corresponding to the pad group 2 on the substrate 1 are centrally symmetrical, and a symmetry center of the multiple marks 7 substantially coincides with a geometric center of the pad group 2. During identifying a theoretical geometric center of the chip 20, the optical inspection system only needs to find the symmetry center of the multiple marks 7 without shift according to the symmetry center of the multiple marks 7. In this way, difficulty of an algorithm in the optical inspection system may be reduced, and the time of the process of detecting the position accuracy of the chips 20 may be reduced.

For example, as shown in FIG. 8B, a pad group 2 corresponds to two marks 7, that is, the two marks 7 are centrally symmetrical. Orthogonal projections of the two marks 7 on the substrate 1 are centrally symmetrical about an orthogonal projection of a geometric center of the pad group 2 on the substrate 1, that is, the symmetry center of the two marks 7 substantially coincides with the geometric center of the pad group 2. In this way, in a case where the geometric center of the pad group 2 coincides with the symmetry center of the corresponding multiple marks 7, the number of the marks 7 is minimized, and the manufacturing cost of the driving backplane 10 may be reduced.

For example, as shown in FIG. 8E, a pad group 2 corresponds to four marks 7, and the four marks 7 are centrally symmetrical. An orthogonal projection of a symmetry center of the four marks 7 on the substrate 1 substantially coincides with an orthogonal projection of the geometric center of the pad group 2 on the substrate 1.

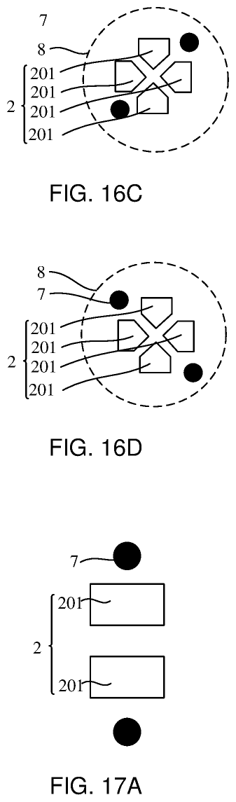

In some embodiments, in a case where the pad group 2 corresponds to two marks 7, as shown in FIG. 16A, a mark 7 is located on an upper side of the pad group 2, and the other mark 7 is located on a lower side of the pad group 2. As shown in FIG. 16B, a mark 7 is located on a left side of the pad group 2, and the other mark 7 is located on a right side of the pad group 2. As shown in FIG. 16C, a mark 7 is located on an upper right side of the pad group 2, and the other mark 7 is located on a lower left side of the pad group 2. As shown in FIG. 16D, a mark 7 is located on an upper left side of the pad group 2, and the other mark 7 is located on a lower right side of the pad group 2. The embodiments of the present disclosure do not limit the position of the marks 7 relative to the pad group 2.

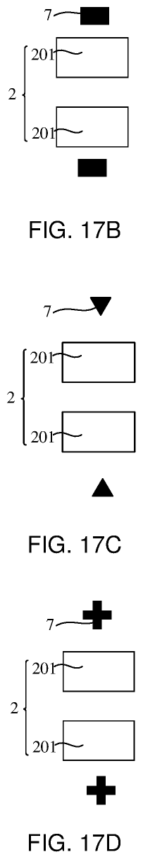

In some embodiments, shapes of orthogonal projections of the marks 7 on the substrate 1 are one or more of circles, rectangles, regular polygons, or crosses. For example, as shown in FIG. 17A, an orthogonal projection of the mark 7 on the substrate 1 is in a shape of a circle. Alternatively, as shown in FIG. 17B, the orthogonal projection of the mark 7 on the substrate 1 is in a shape of a rectangle. Alternatively, as shown in FIG. 17C, the orthogonal projection of the mark 7 on the substrate 1 is in a shape of a regular polygon. Alternatively, as shown in FIG. 17D, the orthogonal projection of the mark 7 on the substrate 1 is in a shape of a cross. For example, the orthogonal projection of the mark 7 on the substrate 1 is in a shape of a circle. The circular mark 7 has a different shape from the first connection line 311, the second connection line 321 and the pad 201, and the circular mark 7 has a high identification success rate. Furthermore, the orthogonal projection of the circular mark 7 on a plane where the substrate 1 is located has a small area.

It can be understood that the shape of the orthogonal projection of the mark 7 on the substrate 1 is not limited to the above shape, as long as the shape of the orthogonal projection of the mark 7 on the substrate 1 can be identified by the optical inspection system.

For example, as shown in FIG. 9, in a case where the orthogonal projection of the mark 7 on the substrate 1 is in a shape of a circle, a radius R1 of the mark may be in a range of 50 μm to 500 μm, inclusive. For example, the radius R1 may be 50 μm, 260 μm, or 500 μm. The embodiments of the present disclosure do not list one by one.

At least one pad 201 in the pad group 2 is bonded to at least one chip 20.

In some embodiments, a gap between chips 20 is relatively large, and a plurality of pads 201 included in the pad group 2 are bonded to a single chip 20. An orthogonal projection of a geometric center of the pad group 2 on the substrate 1 substantially coincides with an orthogonal projection of a symmetry center of multiple marks 7 corresponding to the pad group 2 on the substrate 1.

For example, as shown in FIG. 5A, two pads 201 included in the pad group 2 are bonded to a single chip 20. The orthogonal projection of the geometric center of the pad group 2 on the substrate 1 substantially coincides with an orthogonal projection of a symmetry center of multiple marks 7 corresponding to the pad group 2 on the substrate 1.

For example, as shown in FIG. 5B, four pads 201 included in the pad group 2 are bonded to a single chip 20. The orthogonal projection of the geometric center of the pad group 2 on the substrate 1 substantially coincides with an orthogonal projection of a symmetry center of multiple marks 7 corresponding to the pad group 2 on the substrate 1.

In some embodiments, as shown in FIGS. 18A to 18C, a gap between chips 20 is relatively small, and the number of chips included in the light-emitting substrate 110 is relatively large. The light-emitting substrate 110 may be divided into a plurality of sub-regions (e.g., the number of the sub-regions is in thousands of levels), and each sub-region is independently controlled, thereby improving contrast and brightness of the display device 1000 and improving the user experience.

A plurality of pads 201 included in the pad group 2 are bonded to multiple chips 20. An orthogonal projection of a geometric center of a corresponding area of the plurality of pads 201 bonded to at least one chip 20 on the substrate 1 substantially coincides with an orthogonal projection of a symmetry center of multiple marks 7 on the substrate 1. The geometric center of the corresponding area of the plurality of pads 201 refers to a geometric center of an area composed of the plurality of pads 201 as a whole instead of a geometric center of each pad 201.

For example, as shown in FIGS. 18A to 18C, the plurality of pads 201 included in the pad group 2 are bonded to four chips 20. The plurality of pads 201 may include two first pads 2011, two second pads 2012, two third pads 2013 and a plurality of fourth pads 2014. The two first pads 2011 are bonded to a first light-emitting chip 21 for emitting light of a first color, the two second pads 2012 are bonded to a second light-emitting chip 22 for emitting light of a second color, the two third pads 2013 are bonded to a third light-emitting chip 23 for emitting light of a third color, and the plurality of fourth pads 2014 are bonded to a driver chip 24.

The geometric center of the corresponding area of the plurality of pads 201 bonded to the at least one chip 20 substantially coincides with the symmetry center of the multiple marks 7 means that an orthogonal projection of the geometric center of the corresponding area of the plurality of pads 201 bonded to a chip 20 on the substrate 1 substantially coincides with an orthogonal projection of the symmetry center of the multiple marks 7 on the substrate 1, or an orthogonal projection of the geometric center of the corresponding area of the plurality of pads 201 bonded to multiple chips 20 substantially coincides with an orthogonal projection of the symmetry center of the multiple marks 7 on the substrate 1.

For example, the geometric center of the corresponding area of the two first pads 2011 bonded to the first light-emitting chip 21 substantially coincides with the geometric center of the two marks 7. Alternatively, the geometric center of the corresponding area of the two second pads 2012 bonded to the second light-emitting chip 22 substantially coincides with the geometric center of the two marks 7. Alternatively, the geometric center of the corresponding area of the two third pads 2013 bonded to the third light-emitting chip 23 substantially coincides with the geometric center of the two marks 7. Alternatively, as shown in FIG. 18B, the geometric center of the corresponding area of the plurality of fourth pads 2014 bonded to the driver chip 24 substantially coincides with the geometric center of the two marks 7. The embodiments of the present disclosure do not list one by one.

For example, a geometric center of a corresponding area of a plurality of pads 201 bonded to a first light-emitting chip 21 and a second light-emitting chip 22 substantially coincides with the geometric center of the two marks 7. Alternatively, a geometric center of a corresponding area of a plurality of pads 201 bonded to a first light-emitting chip 21 and a third light-emitting chip 23 substantially coincides with the geometric center of the two marks 7. Alternatively, a geometric center of a corresponding area of a plurality of pads 201 bonded to a first light-emitting chip 21 and a driver chip 24 substantially coincides with the geometric center of the two marks 7. The embodiments of the present disclosure do not list one by one.

For example, as shown in FIG. 18A, a geometric center of a corresponding area of a plurality of pads 201 bonded to a first light-emitting chip 21, a second light-emitting chip 22 and a third light-emitting chip 23 substantially coincides with the geometric center of the two marks 7. The embodiments of the present disclosure do not list one by one.

For example, as shown in FIG. 18C, a geometric center of a corresponding area of a plurality of pads 201 bonded to a first light-emitting chip 21, a second light-emitting chip 22, a third light-emitting chip 23 and a driver chip 24 substantially coincides with the geometric center of the two marks 7. That is, the geometric center of the pad group 2 substantially coincides with the geometric center of the two marks 7.

In some embodiments, as shown in FIGS. 18A to 18C, the two first pads 2011, the two second pads 2012 and the two third pads 2013 are each arranged side by side in the first direction X, and the two first pad 2011, the two second pads 2012 and the two third pads 2013 are arranged in the second direction Y. In the first direction X, the plurality of fourth pads 2014 are located on a side of a whole of the two first pads 2011, the two second pads 2012 and the two third pads 2013. The first direction X intersects the second direction Y. For example, the first direction X and the second direction Y are perpendicular to each other. In a case where the symmetry center of the multiple marks 7 substantially coincides with the geometric center of the two first pads 2011, the two second pads 2012 and the two third pads 2013, the symmetry center of the multiple marks 7 also coincides with a geometric center of the two second pads 2012.

In some embodiments, as shown in FIG. 19, in a case where the two first pads 2011, the two second pads 2012, the two third pads 2013 and the plurality of fourth pads 2014 are not located in the same reference area 8, the plurality of marks 7 include at least one first sub-mark 74 and at least one second sub-mark 75. The at least one first sub-mark 74, the first pads 2011, the two second pads 2012 and the two third pads 2013 are located in a same reference area 8. The at least one second sub-mark 75 and the plurality of fourth pads 2014 are located in another same reference area 8. The first sub-mark 74 and the second sub-mark 75 each include at least one of a first mark 71, a second mark 72 and a third mark 73.

For example, the plurality of marks 7 include two first sub-marks 74 and two second sub-marks 75. In the two first sub-marks 74, a first sub-mark 74 is located on an upper side of the two first pads 2011, and the other first sub-mark 74 is located on a lower side of the two third pads 2013. The two first sub-marks 74 are located in the same reference area 8 as the two first pads 2011, the two second pads 2012 and the two third pads, and a geometric center of the two first sub-marks 74 substantially coincides with a geometric center of the two first pads 2011, the two second pads 2012 and the two third pads 2013. In the two second sub-marks 75, a second sub-marks 75 is located on an upper side of the plurality of fourth pads 2014, and the other second sub-mark 75 is located on a lower side of the plurality of fourth pads 2014.

The theoretical geometric center of the first light-emitting chip 21, the second light-emitting chip 22, and the third light-emitting chip 23 is calculated through the two first sub-marks 74. Therefore, the two first pads 2011, the two second pads 2012 and the two third pads 2013 form a pad group 2.

The theoretical geometric center of the driver chip 24 is calculated through the two second sub-marks 75. Therefore, the plurality of fourth pads 2014 form a pad group 2.

The two second sub-marks 75 and the plurality of fourth pads 2014 are located in the same reference area 8, and the geometric center of the two second sub-marks 75 substantially coincides with the geometric center of the plurality of fourth pads 2014.

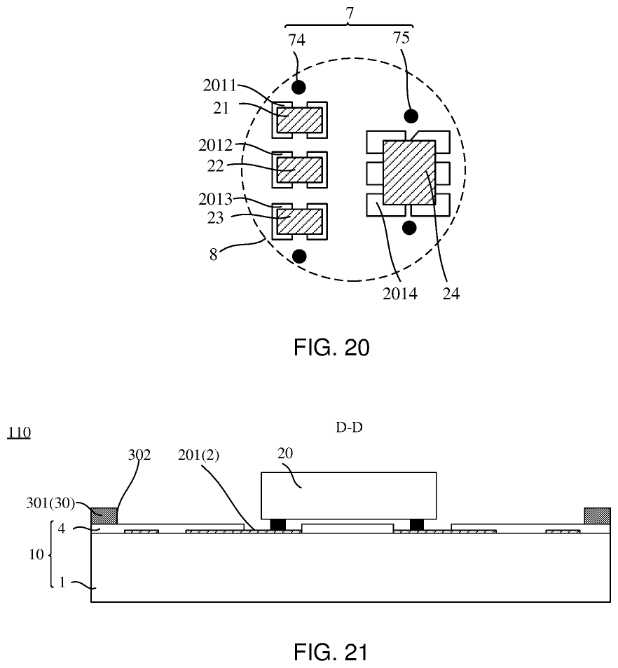

In some embodiments, as shown in FIG. 20, in a case where the two first pads 2011, the two second pads 2012, the two third pads 2013 and the plurality of fourth pads 2014 are located in the same reference area 8, the two first pads 2011, the two second pads 2012, the two third pads 2013 and the plurality of fourth pads 2014 may also be divided into two pad groups. For example, the two first pads 2011, the two second pads 2012 and the two third pads 2013 constitute a pad group and correspond to the two first sub-marks 74, and the plurality of fourth pads 2014 constitute another pad group and correspond to the two second sub-marks 75. Moreover, the two first sub-marks 74 are centrally symmetrical about a geometric center of a whole of the two first pads 2011, the two second pads 2012 and the two third pads 2013, and the two second sub-marks 75 are centrally symmetrical about a geometric center of the plurality of four pads 2014. In this way, the difficulty of the algorithm in the optical inspection system may be reduced, and thus the time of the process of the optical inspection system detecting the position accuracy of the chips 20 may be reduced.

In some embodiments, as shown in FIG. 21, the encapsulation layer 30 is located on a side of the plurality of marks 7 and the plurality of pad groups 2 away from the substrate 1. The encapsulation layer 30 is provided with a plurality of seventh openings 302 therein. An orthogonal projection of a chip 20 on the substrate 1 is located within an orthogonal projection of a seventh opening 302 on the substrate 1, and an orthogonal projection of at least one pad 201 bonded to the chip 20 on the substrate 1 is located within the orthogonal projection of the seventh opening 302 on the substrate 1. In a case where the light-emitting substrate 110 is used as a backlight source, the encapsulation layer 30 includes a reflective layer 301.

In some embodiments, as shown in FIG. 22, an orthogonal projection of at least one mark 7 corresponding to the at least one pad 201 bonded to the chip 20 on the substrate 1 is located within the orthogonal projection of the seventh opening 302 on the substrate 1. In this way, the encapsulation layer 30 will not cover the mark(s) 7 and thus not affect the identification of the mark(s) 7 by the optical inspection system. In a case where the light-emitting substrate 110 is used as a backlight source, the encapsulation layer 30 includes a reflective layer 301. The reflective layer 301 may be formed by a screen transfer printing process, an exposure and development process, or a 3D printing technology. The light-emitting substrate 110 may be formed by a reflective pre-process or a reflective post-process.

In a case where the light-emitting substrate 110 is formed by a reflective pre-process, the reflective layer 301 is formed by a screen transfer printing process or an exposure and development process. The screen transfer printing process has a low cost, and the manufacturing cost of the light-emitting substrate may be reduced. The exposure and development process has a high precise, and the display effect of the light-emitting substrate 110 may be improved.

In a case where the light-emitting substrate 110 is formed by a reflective post-process, the reflective layer 301 is formed by 3D printing technology. The 3D printing has a high degree of freedom. A non-contact adhesive discharge is adopted between a printing nozzle and the substrate 1 to be printed, and a dimensional accuracy corresponding to the reflective layer 301 formed by printing and a dimensional accuracy of the seventh opening 302 are relatively high, which is beneficial to increasing an area ratio of the substrate 1 occupied by the reflective layer 301, thereby increasing the reflectivity of the reflective layer 301, and improving a utilization rate of light emitted by the chip 20.

The thickness printed once is relatively large using the 3D printing process. Therefore, using the 3D printing process may enable the reflective layer 301 to be formed at one time, so that the accuracy of the formed reflective layer 301 may be improved to a certain extent, thereby avoiding an increase in dimensional error after superposition of the reflective layer caused by multiple printings in screen transfer printing, and a step-like morphological characteristic of the reflective layer. Further, the dimensional accuracy of the formed reflective layer 301 may be improved, and there are no grid-like indentations on the surface of the reflective layer 301 formed by the 3D printing process.

Since the chip 20 is first fixed on the substrate 1, and then the reflective layer 301 is formed using the 3D printing process, so that the reflective layer 301 is formed after the die bonding process (here refers to the process of fixing the chip 20 on the substrate 1). As a result, the material of the reflective layer 301 will not be deposited on the pad(s) 201 connected to the chip, and thus a risk of light extinguishing or false soldering caused by the deposition of the material of the reflective layer 301 on the pad 201 may be reduced when the reflective layer 301 is formed first, thereby improving the yield of the light-emitting substrate 110. In addition, risk of a reflow soldering process in the die bonding process causing the reflectivity of the reflective layer 301 to decrease may also be reduced, thereby improving the light efficiency of the reflective layer 301 and improving luminous efficiency of the light-emitting substrate 110. Further, the display brightness of the backlight module 100 and the display device 1000 may be improved, and the power consumption of the backlight module 100 and the display device 1000 may be reduced.

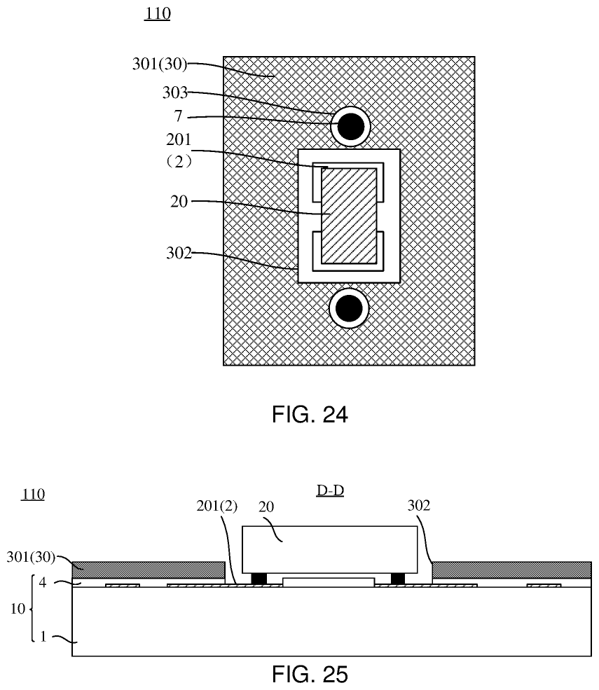

In some embodiments, as shown in FIGS. 23 and 24, the encapsulation layer 30 is further provided with a plurality of eighth openings 303 therein, and an orthogonal projection of at least one mark 7 corresponding to at least one pad 201 bonded to a chip 20 on the substrate 1 is located within an orthogonal projection of an eighth opening 303 on the substrate 1. In this way, the encapsulation layer 30 will not cover the mark(s) 7 and thus not affect the identification of the mark(s) 7 by the optical inspection system. In a case where the light-emitting substrate 110 is used as a backlight source, the encapsulation layer 30 includes a reflective layer 301. The reflective layer 301 may be formed by a screen transfer printing process, an exposure and development process, or a 3D printing technology. The light-emitting substrate 110 may be formed by a reflective pre-process or a reflective post-process.

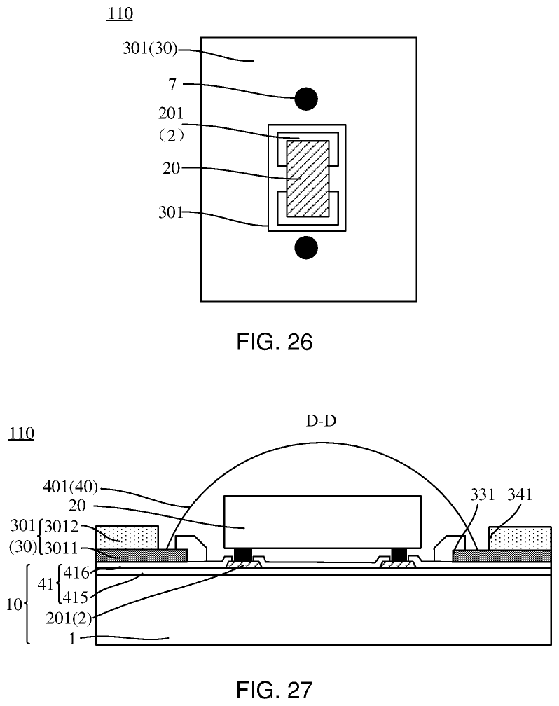

In some embodiments, as shown in FIGS. 25 to 26, orthogonal projections of the plurality of marks 7 on the substrate 1 are located within an orthogonal projection of the encapsulation layer 30 on the substrate 1. If the encapsulation layer 30 is formed before a die bonding step, the encapsulation layer 30 covers the marks 7, which may affect the identification of the marks 7 by the optical inspection system. If the encapsulation layer 30 is formed after the die bonding step, in this case, the die bonding has been completed and the function of the marks 7 have been realized, coverage of the marks 7 by the encapsulation layer 30 will not have an influence. In a case where the light-emitting substrate 110 is used as a backlight, the encapsulation layer 30 includes a reflective layer 301. The reflective layer 301 has a relatively large area, and the risk of light shadows may be reduced. The reflective layer 301 is formed by 3D printing technology, and thus the risk of the chip 20 that has been bonded to the driving backplane 10 falling off may be reduced. The light-emitting substrate 110 may be formed by a reflective pre-process.

In some embodiments, as shown in FIG. 27 (the mark 7 is not shown in the figure), in a case where the driving backplane 10 includes the first conductive layer 31 and the first insulating layer 41, the first insulating layer 41 includes a first insulating sub-layer 415 and a second insulating sub-layer 416. The first insulating sub-layer 415 is closer to the substrate 1 than the second insulating sub-layer 416. The first conductive layer 31 is located between the first insulating sub-layer 415 and the second insulating sub-layer 416.

In a case where the light-emitting substrate 110 is used as a backlight source, the reflective layer 301 includes a first reflective sub-layer 3011 and a second reflective sub-layer 3012. The first reflective sub-layer 3011 is closer to the first insulating layer 41 than the second reflective sub-layer 3012. For example, the material of the first reflective sub-layer 3011 includes white ink, and the second reflective sub-layer 3012 is a reflective sheet. The first reflective sub-layer 3011 is provided with a plurality of eleventh openings 331 therein, and the second reflective sub-layer 3012 is provided with a plurality of twelfth openings 341 therein. An eleventh opening 331 and a twelfth opening 341 constitute a seventh opening 302 as above.

The light-emitting substrate 110 further includes a protective layer 40. The protective layer 40 is located on a side of the chip 20 away from the first insulating layer 41. The protective layer 40 is configured to encapsulate the chip 20. The protective layer 40 may reduce the risk of moisture in the air entering the chip 20, thereby improving the service life of the chip 20.

For example, as shown in FIG. 27, the protective layer 40 includes a plurality of protective sub-layers 401. A protective sub-layer 401 is configured to protect the chip(s) 20 corresponding to a pad group 2, and the protective sub-layer 401 is located inside a twelfth opening 341.

For example, the protective layer 40 may include a whole layer of protective layer 40, and the whole layer of protective layer 40 covers the plurality of chips 20.

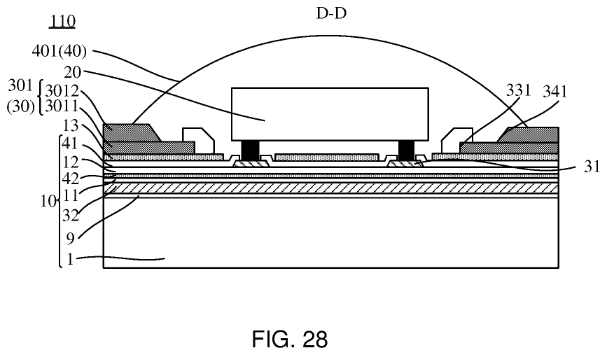

In some embodiments, as shown in FIG. 28 (the mark 7 is not shown in the figure), in a case where the driving backplane 10 includes the second conductive layer 32 and the second insulating layer 42, the driving backplane 10 further includes a first passivation layer 9, a second passivation layer 11, a third passivation layer 12 and a fourth passivation layer 13.

The first passivation layer 9 is located between the second conductive layer 32 and the substrate 1, the second passivation layer 11 is located between the second conductive layer 32 and the second insulating layer 42, the third passivation layer 12 is located on a side of the second insulating layer 42 away from the second passivation layer 11, the first conductive layer 31 is located on a side of the third passivation layer 12 away from the second insulating layer 42, and the fourth passivation layer 13 is located on a side of the first insulating layer 41 away from the third passivation layer 12.

The encapsulation layer 30 includes a first reflective sub-layer 3011 and a second reflective sub-layer 3012. The first reflective sub-layer 3011 is closer to the first insulating layer 41 than the second reflective sub-layer 3012. For example, the materials of the first reflective sub-layer 3011 and the second reflective sub-layer 3012 both include white ink. The first reflective sub-layer 3011 is provided with a plurality of eleventh openings 331 therein, and the second reflective sub-layer 3012 is provided with a plurality of twelfth openings 341 therein. An eleventh opening 331 and a twelfth opening 341 constitute a seventh opening 302 as above.

The light-emitting substrate 110 further includes a protective layer 40. The protective layer 40 is located on a side of the chip 20 away from the first insulating layer 41. The protective layer 40 is configured to encapsulate the chip 20. The protective layer 40 may reduce the risk of moisture in the air entering the chip 20, thereby improving the service life of the chip 20.

For example, as shown in FIG. 28, the protective layer 40 includes a plurality of protective sub-layers 401. A protective sub-layer 401 is configured to protect the chip(s) 20 corresponding to a pad group 2. The protective sub-layer 401 is located on a side of the second reflective sub-layer 3012 away from the first reflective sub-layer 3011 and is fixedly connected to the second reflective sub-layer 3012.

For example, the protective layer 40 may include a whole layer of protective layer 40, and the whole layer of protective layer 40 covers the plurality of chips 20.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A driving backplane, comprising:
a substrate;
a plurality of pad groups located on a side of the substrate, a pad group including one or more pads; and
a plurality of marks located on a same side of the substrate as the plurality of pad groups, orthogonal projections of the plurality of marks on the substrate being not overlapped with orthogonal projections of the plurality of pad groups on the substrate; wherein
the pad group corresponds to one or more marks, and orthogonal projections of the one or more marks on the substrate are located on a circumference of an orthogonal projection of a corresponding area of the pad group on the substrate, are each adjacent to an orthogonal projection of the pad group on the substrate, and each have a gap from the orthogonal projection of the pad group on the substrate.

2. The driving backplane according to claim 1, wherein the pad group corresponds to multiple marks; and orthogonal projections of the multiple marks on the substrate are arranged at intervals along the circumference of the orthogonal projection of the corresponding area of the pad group on the substrate.

3. The driving backplane according to claim 1, wherein the pad group corresponds to multiple marks; an orthogonal projection of a geometric center of each mark on the substrate has an approximately equal distance from an orthogonal projection of a geometric center of the corresponding area of the pad group on the substrate, and an orthogonal projection of a geometric center of the multiple marks on the substrate substantially coincides with the orthogonal projection of the geometric center of the corresponding area of the pad group on the substrate.

4. (canceled)

5. The driving backplane according to claim 1, further comprising:
at least one conductive layer located on the side of the substrate, each conductive layer including a plurality of connection lines; and
one or more insulating layers, an insulating layer being included on a side of the at least one conductive layer away from the substrate; and in a case where the driving backplane comprises a plurality of conductive layers, at least one insulating layer being included between two adjacent conductive layers; wherein
the plurality of marks are disposed in the at least one conductive layer.

6. The driving backplane according to claim 5, wherein the plurality of marks include at least one first mark, and a conductive layer where the first mark is located is a first target conductive layer; and
an orthogonal projection of the first mark on the substrate is not overlapped with orthogonal projections of a plurality of connection lines in the first target conductive layer on the substrate.

7. (canceled)

8. The driving backplane according to claim 5, wherein the plurality of marks include at least one third mark, and a conductive layer where the third mark is located is a third target conductive layer; the one or more insulating layers include an upper insulating layer, and the upper insulating layer is located on a side of the third target conductive layer away from the substrate;
the upper insulating layer is provided with a plurality of first openings therein, and an orthogonal projection of a first opening on the substrate is located within an orthogonal projection of a connection line in the third target conductive layer on the substrate; wherein
a portion of the connection line located in the first opening serves as a third mark.

9. The driving backplane according to claim 8, wherein the connection line where the third mark is located is a target connection line, and the target connection line includes a first extension section and a second extension section; and
the orthogonal projection of the first opening on the substrate is located within an orthogonal projection of the first extension section on the substrate, a line width of the first extension section is greater than a line width of the second extension section, and a shape of at least one side edge of the first extension section is substantially same as a shape of at least part of a border of the first opening.

10. The driving backplane according to claim 5, wherein
the at least one conductive layer includes a first conductive layer, the first conductive layer is located on the side of the substrate, and the first conductive layer includes a plurality of first connection lines; and
the one or more insulating layers include a first insulating layer, the first insulating layer is located on a side of the first conductive layer away from the substrate; wherein
the plurality of marks are disposed in the first conductive layer.

11. The driving backplane according to claim 5, wherein
the at least one conductive layer includes a first conductive layer and a second conductive layer, the first conductive layer is further away from the substrate than the second conductive layer; the first conductive layer includes a plurality of first connection lines, and the second conductive layer includes a plurality of second connection lines; and
the one or more insulating layers include a first insulating layer and a second insulating layer, the first insulating layer is located on a side of the first conductive layer away from the substrate, and the second insulating layer is located between the first conductive layer and the second conductive layer; wherein
the plurality of marks are disposed in the first conductive layer and/or the second conductive layer, and the plurality of marks include at least one of a first mark, a second mark and a third mark.

12. The driving backplane according to claim 10, wherein
the plurality of marks are disposed in the first conductive layer, and the plurality of marks include at least one of a first mark and a second mark; and
a material of the first insulating layer includes a transparent material; and/or the first insulating layer is provided with a plurality of second openings therein, and an orthogonal projection of a mark on the substrate is at least partially located within an orthogonal projection of a second opening on the substrate.

13. The driving backplane according to claim 10, wherein the plurality of marks are disposed in the first conductive layer, and the plurality of marks include a plurality of third marks; and
a material of the first insulating layer includes a photoresist material.

14. (canceled)

15. (canceled)

16. (canceled)

17. The driving backplane according to claim 1, wherein the pad group corresponds to multiple marks; orthogonal projections of the multiple marks corresponding to the pad group on the substrate are centrally symmetrical, and an orthogonal projection of a symmetry center of the multiple marks on the substrate substantially coincides with an orthogonal projection of a geometric center of the pad group on the substrate, wherein the geometric center of the pad group refers to a geometric center of the corresponding area of the pad group.

18. The driving backplane according to claim 1, wherein the pad group corresponds to two marks, and orthogonal projections of the two marks on the substrate are centrally symmetrical about the geometric center of the pad group.

19. The driving backplane according to claim 1, wherein the pad group includes a plurality of pads, and the plurality of pads are configured to be bonded to a same chip; the pad group corresponds to multiple marks; and an orthogonal projection of a geometric center of the pad group on the substrate substantially coincides with an orthogonal projection of a symmetry center of the multiple marks corresponding to the pad group on the substrate.

20. The driving backplane according to claim 1, wherein the pad group includes a plurality of pads, and the plurality of pads are configured to be bonded to a plurality of chips; the pad group corresponds to multiple marks; and an orthogonal projection of a geometric center of a corresponding area of multiple pads bonded to at least one chip on the substrate substantially coincides with an orthogonal projection of a symmetry center of at least part of the multiple marks on the substrate.

21. The driving backplane according to claim 20, wherein the pad group includes two first pads, two second pads, two third pads and a plurality of fourth pads; the two first pads are configured to be bonded to a first light-emitting chip for emitting light of a first color, the two second pads are configured to be bonded to a second light-emitting chip for emitting light of a second color, the two third pads are configured to be bonded to a third light-emitting chip for emitting light of a third color, and the plurality of fourth pads are configured to be bonded to a driver chip; and
the orthogonal projection of the symmetry center of the at least part of the multiple marks on the substrate substantially coincides with an orthogonal projection of a geometric center of a whole of the two first pads, the two second pads and the two third pads on the substrate, or substantially coincides with an orthogonal projection of a geometric center of the plurality of four pads on the substrate, or substantially coincides with an orthogonal projection of a geometric center of the pad group on the substrate.

22. The driving backplane according to claim 21, wherein the two first pads, the two second pads and the two third pads are each arranged side by side in a first direction, and the two first pads, the two second pads and the two third pads are arranged in a second direction; the first direction intersects the second direction; and
in the first direction, the plurality of fourth pads are located on a side of the whole of the two first pads, the two second pads and the two third pads.

23. The driving backplane according to claim 1, wherein shapes of orthogonal projections of the marks on the substrate are one or more of a circle, a rectangle, a regular polygon, or a cross.

24. A light-emitting substrate, comprising:
the driving backplane according to claim 1, wherein
a plurality of chips, a chip being bonded to at least one pad of the one or more pads in the pad group; and
an encapsulation layer located on a side of the plurality of marks and the plurality of pad groups away from the substrate, and provided with a plurality of seventh openings therein, wherein an orthogonal projection of the at least one pad bonded to the chip on the substrate is located within an orthogonal projection of a seventh opening on the substrate.

25. (canceled)

26. (canceled)

27. (canceled)

28. (canceled)

29. A display device, comprising:
the light-emitting substrate according to claim 24, the encapsulation layer of the light-emitting substrate including a reflective layer;
an optical film disposed on a light-exiting side of the light-emitting substrate; and
a display panel disposed on a light-exiting side of the backlight module.

30. (canceled)
